(19) United States
(12) Patent Application Publication
(10) Pub. No.: US 2012/0134008 A1
(43) Pub. Date: May 31, 2012

(54) ELECTROMECHANICAL INTERFEROMETRIC MODULATOR DEVICE

(76) Inventors: Ion Bita, San Jose, CA (US); Sapna Patel, Fremont, CA (US)

(21) Appl. No.: 12/956,931

(22) Filed: Nov. 30, 2010

(51) Int. Cl. G02B 26/00; H05K 3/10

(52) U.S. Cl. 359/295; 359/291; 427/97.3

(57) ABSTRACT

This disclosure provides systems, methods and apparatus for an electromechanical system. In one aspect, an electromechanical interferometric modulator system includes a substrate and a plurality of interferometric modulators (IMODs). At least two different IMOD types correspond to different reflected colors. Each IMOD has an optical stack, an absorber layer, a movable reflective layer, where the movable reflective layer has at least open and collapsed states, and an air gap defined between the movable reflective layer and the optical stack in the open state. The optical stacks define different optical path lengths for each of the different IMOD types by way of different transparent layer thickness and/or material, while the air gap has the same size when in the open state. The IMODs reflect different colors in the closed state and a common appearance in the open state. Use of two absorbers aids in defining the common appearance in the open state and can also improve color saturation.

### TECHNICAL FIELD

This disclosure relates to electromechanical systems.

### DESCRIPTION OF THE RELATED TECHNOLOGY

Electromechanical systems include devices having electrical and mechanical elements, actuators, transducers, sensors, optical components (e.g., mirrors) and electronics. Electromechanical systems can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of electromechanical systems device is called an interferometric modulator (IMOD). As used herein, the term interferometric modulator or interferometric light modulator refers to a device that selectively absorbs and/or reflects light using the principles of optical interference. In some implementations, an interferometric modulator may include a pair of conductive plates, one or both of which may be transparent and/or reflective, wholly or in part, and capable of relative motion upon application of an appropriate electrical signal. In an implementation, one plate may include a stationary layer deposited on a substrate and the other plate may include a reflective membrane separated from the stationary layer by an air gap. The position of one plate in relation to another can change the optical interference of light incident on the interferometric modulator. Interferometric modulator devices have a wide range of applications, and are anticipated to be used in improving existing products and creating new products, especially those with display capabilities.

### SUMMARY

The systems, methods and devices of the disclosure each have several innovative aspects, no single one of which is solely responsible for the desirable attributes disclosed herein.

One innovative aspect of the subject matter described in this disclosure can be implemented in an electromechanical interferometric modulator system. The system includes a substrate and a plurality of interferometric modulators (IMODs). Each IMOD includes an optical stack formed on the substrate, where the optical stack includes a first absorber layer. Each IMOD further includes a movable reflective layer where the movable reflective layer has at least open and collapsed states, and a gap defined between the movable reflective layer and the optical stack in the open state. The IMODs include at least two different IMOD types corresponding to different reflected visible wavelengths in one of the states, where the optical stack defines different optical path lengths for each of the at least two different IMOD types, and the gap has the same size in the open state for each of the at least two different IMOD types.

The optical stack of the electromechanical interferometric modulator system can include a transparent solid layer between the first absorber layer and the movable reflective layer, where the transparent solid layer has a different thickness for each of the different IMOD types. In some implementations, the optical stack can further include a second absorber layer between the transparent solid layer and the gap in the open state. In some implementations, the optical stack of the electromechanical interferometric modulator system can further include a planarization layer between the transparent solid layer and the gap, the planarization layer having different thicknesses for each of the different IMOD types complementing the different thicknesses of the transparent solid layer for the different IMOD types to define a uniform total thickness of the optical stack for the different IMOD types, and where the transparent solid layer has a refractive index different from the refractive index of the planarization layer for each of the different IMOD types. Additionally, in some implementations, the plurality of interferometric modulators can form a color display.

Another innovative aspect of the subject matter described in this disclosure can be implemented in an electromechanical interferometric modulator color display system. The system includes a substrate and a plurality of interferometric modulators (IMODs). Each IMOD includes an optical stack formed on the substrate, where the optical stack includes a dielectric layer, a first absorber layer on one side of the dielectric layer and a second absorber layer on an opposite side of the dielectric layer. Each IMOD further includes a movable reflective layer, where the movable reflective layer has at least open and collapsed states, and an air gap defined between the movable reflective layer and the optical stack in the open state.

In accordance with another innovative aspect of the subject matter described in this disclosure, an electromechanical systems device is provided. The system includes a substrate and a stationary electrode over the substrate. The stationary electrode includes a first absorber layer over the substrate, a transparent solid layer over the first absorber layer, and a second absorber layer over the dielectric layer. The system further includes a movable electrode over the stationary electrode, where the movable electrode has at least open and collapsed states, and the stationary electrode and the movable electrode define a gap therebetween in the open state.

In accordance with another innovative aspect of the subject matter described in this disclosure can be implemented in an electromechanical interferometric modulator system with at least two different interferometric modulator (IMOD) types for reflecting corresponding different colors. The system includes means for supporting the electromechanical interferometric modulator system and means for defining optical path length within each of the at least two different IMOD types, the means for defining optical path length being different for each of the at least two different IMOD types and being positioned over the means for supporting. The system further includes first means for absorbing light, where the first means for absorbing is positioned between the means for defining optical path length and the means for supporting for each of the at least two different IMOD types, means for reflecting light, where the means for reflecting is positioned over the means for defining optical path length for each of the at least two different IMOD types, and means for moving the means for reflecting through a commonly sized gap for each of the at least two different IMOD types, where the means for moving define at least open and collapsed states.

The means for defining optical path length of the electromechanical interferometric modulator system can each include a transparent solid dielectric material. The transparent solid layer also can have a different thickness for each of the at least two different IMOD types. In some implementations, the electromechanical interferometric modulator system can further include second means of absorbing light, where the second means for absorbing is positioned between the means for defining optical path length and the gap for each of the at least two different IMOD types.

In accordance with another innovative aspect of the subject matter described in this disclosure can be implemented in a method of manufacturing at least a first electromechanical interferometric modulator (IMOD), a second IMOD, and a third IMOD in first, second, and third regions, respectively. The method includes providing a transparent substrate, forming a first absorber layer over the substrate, forming a first transparent solid layer over the absorber layer in the first region, forming a second transparent solid layer over the absorber layer in the second region, forming a third transparent solid layer over the absorber layer in the third region, and forming a movable reflective layer over each of the transparent solid layers, where the movable reflective layer has at least open and collapsed states, and the movable reflective layer and each of the transparent solid layers define a gap therebetween in the open state, where the gap has the same height in the open state in the first, second, and third regions. The first, second, and third transparent solid layers each define different optical path lengths representing different colors for one of the open and collapsed states in the first, second, and third regions, respectively.

The method of forming the third transparent solid layer can include forming a planarization layer, where the planarization layer defines a substantially planar surface at a common height above the substrate in each of the first, second, and third regions between the gap and the corresponding transparent solid layer.

Another innovative aspect of the subject matter described in this disclosure can be implemented in a method of manufacturing an electromechanical interferometric modulator device. The method includes providing a transparent substrate, forming a first absorber layer over the substrate, forming a dielectric layer over the first absorber layer, forming a second absorber layer over the dielectric layer, and forming a movable reflective layer over the dielectric layer, where the movable reflective layer has at least open and collapsed states, and where the dielectric layer and the reflective layer define a gap therebetween in the open state.

Another innovative aspect of the subject matter described in this disclosure can be implemented in a method of operating an electromechanical interferometric modulator (IMOD) device. The method includes providing a substrate and at least two IMODs of different types. Each of the at least two IMODs of different types further includes an optical stack formed on the substrate, a movable reflective layer, and a gap defined between the movable reflective layer and the optical stack. The optical stack further includes a dielectric layer and an absorber layer formed between the dielectric layer and the substrate. The method includes actuating the movable reflective layer in a first IMOD type of the at least two IMODs of different types toward the optical stack to substantially close the gap in the first IMOD type, and reflecting a first color upon actuating the movable reflective layer in the first IMOD type. The method further includes actuating the movable reflective layer in a second IMOD type of the at least two IMODs of different types toward the optical stack to substantially close the gap in the second IMOD type, and reflecting a second color different from the first color upon actuating the movable reflective layer in the second IMOD type.

The method can further include relaxing the movable reflective layer in the first IMOD type away from the optical stack to substantially open the gap in the first IMOD type, producing an open state visible appearance upon relaxing the movable reflective layer in the first IMOD type, relaxing the movable reflective layer in the second IMOD type away from the optical stack to substantially open the gap in the second IMOD type, and producing substantially the same open state visible appearance upon relaxing the movable reflective layer in the second IMOD type. In some implementations, the movable reflective layer can have at least open and closed states, where the gap for each of the at least two IMODs of different types can have the same height in the open state.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example of an isometric view depicting two adjacent pixels in a series of pixels of an interferometric modulator (IMOD) display device.

FIG. 2 shows an example of a system block diagram illustrating an electronic device incorporating a 3×3 interferometric modulator display.

FIG. 3 shows an example of a diagram illustrating movable reflective layer position versus applied voltage for the interferometric modulator of FIG. 1.

FIG. 4 shows an example of a table illustrating various states of an interferometric modulator when various common and segment voltages are applied.

FIG. 5A shows an example of a diagram illustrating a frame of display data in the 3×3 interferometric modulator display of FIG. 2.

FIG. 5B shows an example of a timing diagram for common and segment signals that may be used to write the frame of display data illustrated in FIG. 5A.

FIG. 6A shows an example of a partial cross-section of the interferometric modulator display of FIG. 1.

FIGS. 6B-6E show examples of cross-sections of varying implementations of interferometric modulators.

FIG. 7 shows an example of a flow diagram illustrating a manufacturing process for an interferometric modulator.

FIGS. 7A-7E show examples of cross-sectional schematic illustrations of various stages in a method of making an interferometric modulator.

FIG. 8A shows an example of a schematic cross section of an implementation of three different interferometric modulators, corresponding to three different colors, with all three shown in the open state having a constant air gap and three different dielectric thicknesses.

FIG. 8B shows an example of a schematic cross section of the interferometric modulators of FIG. 8A in the closed state.

FIG. 8C shows an example of a schematic cross section of another implementation showing three different interferometric modulators, all three shown in the open state having a constant air gap and three different dielectric materials.

FIG. 9A shows an example of a schematic cross section of an alternative implementation showing three different interferometric modulators having a constant air gap and a planarization layer formed over dielectric layers of different thicknesses.

FIG. 9B shows an example of a schematic cross section of the interferometric modulators of FIG. 9A in the closed state.

FIG. 9C shows an example of a schematic cross section of another implementation showing three different interferometric modulators in the open state having a constant air gap and a planarization layer formed over three different dielectric materials.

FIG. 10A shows an example of a reflectivity curve for a blue interferometric modulator in open and closed states in accordance with a constant gap implementation.

FIG. 10B shows an example of a reflectivity curve for a green interferometric modulator in open and closed states, having the same gap in the open state as the blue interferometric modulator of FIG. 10A.

FIG. 10C shows an example of a reflectivity curve for a red interferometric modulator in open and closed states, having the same gap in the open state as the blue and green interferometric modulators of FIGS. 10A and 10B.

FIGS. 11A and 11B show examples of system block diagrams illustrating a display device that includes a plurality of interferometric modulators.

FIG. 12 shows an example of a flow diagram illustrating a manufacturing process for an interferometric modulator.

FIG. 13 shows another example of a flow diagram illustrating a manufacturing process for an interferometric modulator.

FIG. 14 shows an example of a flow diagram illustrating a method of operating an electromechanical interferometric modulator device.

Like reference numbers and designations in the various drawings indicate like elements.

### DETAILED DESCRIPTION

The following detailed description is directed to certain implementations for the purposes of describing the innovative aspects. However, the teachings herein can be applied in a multitude of different ways. The described implementations may be implemented in any device that is configured to display an image, whether in motion (e.g., video) or stationary (e.g., still image), and whether textual, graphical or pictorial. More particularly, it is contemplated that the implementations may be implemented in or associated with a variety of electronic devices such as, but not limited to, mobile telephones, multimedia Internet enabled cellular telephones, mobile television receivers, wireless devices, smartphones, bluetooth devices, personal data assistants (PDAs), wireless electronic mail receivers, hand-held or portable computers, netbooks, notebooks, smartbooks, printers, copiers, scanners, facsimile devices, GPS receivers/navigators, cameras, MP3 players, camcorders, game consoles, wrist watches, clocks, calculators, television monitors, flat panel displays, electronic reading devices (e.g., e-readers), computer monitors, auto displays (e.g., odometer display, etc.), cockpit controls and/or displays, camera view displays (e.g., display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, packaging (e.g., MEMS and non-MEMS), aesthetic structures (e.g., display of images on a piece of jewelry) and a variety of electromechanical systems devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes, electronic test equipment. Thus, the teachings are not intended to be limited to the implementations depicted solely in the Figures, but instead have wide applicability as will be readily apparent to one having ordinary skill in the art.

In some implementations, an electromechanical systems interferometric modulator device can have a plurality of interferometric modulators forming a color or grayscale display. Each interferometric modulator is one of at least two different interferometric modulator types, where the different interferometric modulator types are differently configured to produce different interferometric reflected colors (e.g., red-green-blue for RGB displays) or shades (e.g., grayscale). Despite being capable of interferometrically reflecting different colors or wavelengths in one of the open or collapsed states, the different interferometric modulator types can have the same sized air gap in the open state. For example, the different interferometric modulator types can appear dark in the open state with common gap sizes, whereas the optical path lengths and hence reflected color/shade for the at least two different interferometric modulator types can be different in the collapsed state. The thicknesses and/or materials of the transparent layers for each of the at least two different interferometric modulator types can be different. Each of the optical stacks can include two absorbers situated on opposite sides of the transparent layer, which can aid in tuning color saturation for the interferometric modulators in one state (e.g., open) and also aid in achieving a common background state (e.g., dark) in the other state (e.g., closed).

Particular implementations of the subject matter described in this disclosure can be implemented to realize one or more of the following potential advantages. A constant or same-sized air gap in the open state for each IMOD type can reduce the complexity of fabricating IMOD structures by requiring the deposition of only a single thickness for the sacrificial layer. A person having ordinary skill in the art will readily recognize that a single gap size also can reduce etch attack issues and etch-related non-uniformity entailed by multiple air gap sizes. Multiple air gap sizes are produced by etching sacrificial layers of different thicknesses, which would expose structural materials to the etchants for longer periods of time after smaller thicknesses of sacrificial material were removed and the larger thicknesses are still being removed. Furthermore, defining a single air gap can employ fewer depositions, fewer masks, and reduced material consumption may ultimately reduce the cost and improve efficiency of fabricating IMOD structures. Another potential advantage is that with a constant air gap, a single actuation voltage can be employed for the different IMODs without altering stiffness for the mechanical layers of different IMOD types (e.g., different IMOD colors/shades). Finally, independent of the above advantages, the use of two optical absorbers within an optical stack can provide an additional variable to tune aspects of image quality, such as color saturation.

One example of a suitable MEMS device, to which the described implementations may apply, is a reflective display device. Reflective display devices can incorporate interferometric modulators (IMODs) to selectively absorb and/or reflect light incident thereon using principles of optical interference. IMODs can include an absorber, a reflector that is movable with respect to the absorber, and an optical resonant cavity defined between the absorber and the reflector. The reflector can be moved to two or more different positions, which can change the size of the optical resonant cavity and thereby affect the reflectance of the interferometric modulator. The reflectance spectrums of IMODs can create fairly broad spectral bands which can be shifted across the visible wavelengths to generate different colors. The position of the spectral band can be adjusted by changing the thickness of the optical resonant cavity, i.e., by changing the position of the reflector.

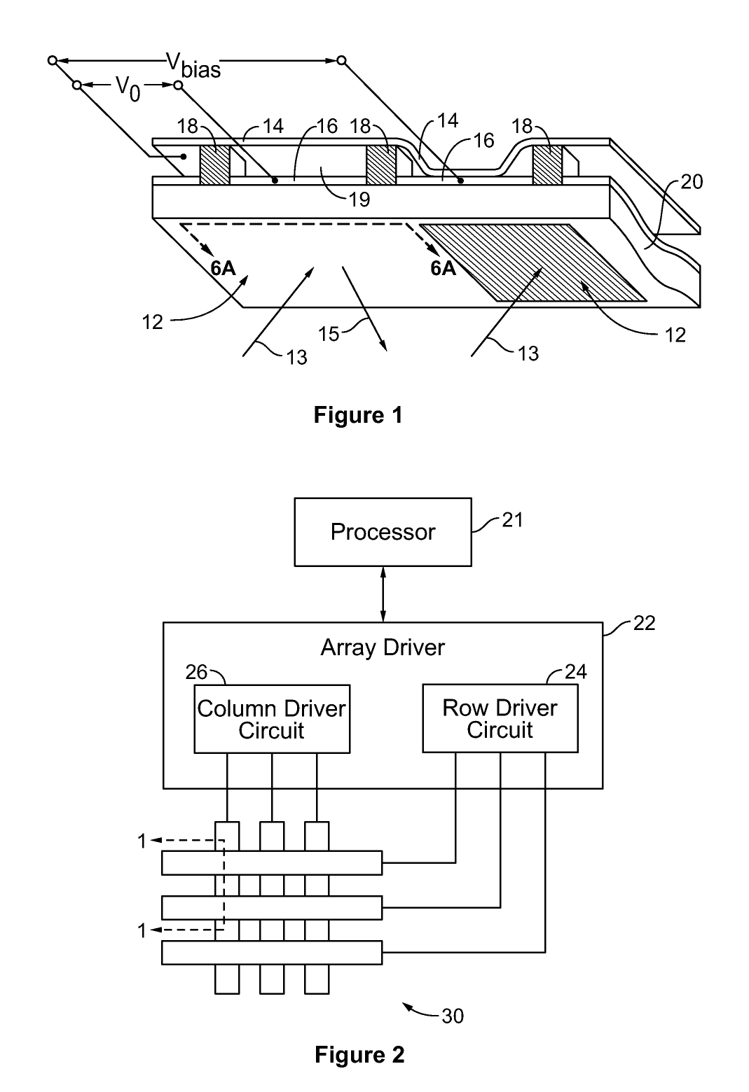

FIG. 1 shows an example of an isometric view depicting two adjacent pixels in a series of pixels of an interferometric modulator (IMOD) display device. The IMOD display device includes one or more interferometric MEMS display elements. In these devices, the pixels of the MEMS display elements can be in either a bright or dark state. In the bright (“relaxed,” “open” or “on”) state, the display element reflects a large portion of incident visible light, e.g., to a user. Conversely, in the dark (“actuated,” “closed” or “off”) state, the display element reflects little incident visible light. In some implementations, the light reflectance properties of the on and off states may be reversed. MEMS pixels can be configured to reflect predominantly at particular wavelengths allowing for a color display in addition to black and white.

The IMOD display device can include a row/column array of IMODs. Each IMOD can include a pair of reflective layers, i.e., a movable reflective layer and a fixed partially reflective layer, positioned at a variable and controllable distance from each other to form an air gap (also referred to as an optical gap or cavity). The movable reflective layer may be moved between at least two positions. In a first position, i.e., a relaxed position, the movable reflective layer can be positioned at a relatively large distance from the fixed partially reflective layer. In a second position, i.e., an actuated position, the movable reflective layer can be positioned more closely to the partially reflective layer. Incident light that reflects from the two layers can interfere constructively or destructively depending on the position of the movable reflective layer, producing either an overall reflective or non-reflective state for each pixel. In some implementations, the IMOD may be in a reflective state when unactuated, reflecting light within the visible spectrum, and may be in a dark state when unactuated, reflecting light outside of the visible range (e.g., infrared light). In some other implementations, however, an IMOD may be in a dark state when unactuated, and in a reflective state when actuated. In some implementations, the introduction of an applied voltage can drive the pixels to change states. In some other implementations, an applied charge can drive the pixels to change states.

The depicted portion of the pixel array in FIG. 1 includes two adjacent interferometric modulators 12. In the IMOD 12 on the left (as illustrated), a movable reflective layer 14 is illustrated in a relaxed position at a predetermined distance from an optical stack 16, which includes a partially reflective layer. The voltage V₀ applied across the IMOD 12 on the left is insufficient to cause actuation of the movable reflective layer 14. In the IMOD 12 on the right, the movable reflective layer 14 is illustrated in an actuated position near or adjacent the optical stack 16. The voltage V_{bias} applied across the IMOD 12 on the right is sufficient to maintain the movable reflective layer 14 in the actuated position.

In FIG. 1, the reflective properties of pixels 12 are generally illustrated with arrows 13 indicating light incident upon the pixels 12, and light 15 reflecting from the pixel 12 on the left. Although not illustrated in detail, it will be understood by one having ordinary skill in the art that most of the light 13 incident upon the pixels 12 will be transmitted through the transparent substrate 20, toward the optical stack 16. A portion of the light incident upon the optical stack 16 will be transmitted through the partially reflective layer of the optical stack 16, and a portion will be reflected back through the transparent substrate 20. The portion of light 13 that is transmitted through the optical stack 16 will be reflected at the movable reflective layer 14, back toward (and through) the transparent substrate 20. Interference (constructive or destructive) between the light reflected from the partially reflective layer of the optical stack 16 and the light reflected from the movable reflective layer 14 will determine the wavelength(s) of light 15 reflected from the pixel 12.

The optical stack 16 can include a single layer or several layers. The layer(s) can include one or more of an electrode layer, a partially reflective and partially transmissive layer and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals, e.g., chromium (Cr), semiconductors, and dielectrics. The partially reflective layer can be formed of one or more layers of materials, and each of the layers can be formed of a single material or a combination of materials. In some implementations, the optical stack 16 can include a single semi-transparent thickness of metal or semiconductor which serves as both an optical absorber and conductor, while different, more conductive layers or portions (e.g., of the optical stack 16 or of other structures of the IMOD) can serve to bus signals between IMOD pixels. The optical stack 16 also can include one or more insulating or dielectric layers covering one or more conductive layers or a conductive/absorptive layer.

In some implementations, the layer(s) of the optical stack 16 can be patterned into parallel strips, and may form row electrodes in a display device as described further below. As will be understood by one having skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of posts 18 and an intervening sacrificial material deposited between the posts 18. When the sacrificial material is etched away, a defined gap 19, or optical cavity, can be formed between the movable reflective layer 14 and the optical stack 16. In some implementations, the spacing between posts 18 may be on the order of 1-1000 um, while the gap 19 may be on the order of <10,000 Angstroms (Å).

In some implementations, each pixel of the IMOD, whether in the actuated or relaxed state, is essentially a capacitor formed by the fixed and moving reflective layers. When no voltage is applied, the movable reflective layer 14a remains in a mechanically relaxed state, as illustrated by the pixel 12 on the left in FIG. 1, with the gap 19 between the movable reflective layer 14 and optical stack 16. However, when a potential difference, e.g., voltage, is applied to at least one of a selected row and column, the capacitor formed at the intersection of the row and column electrodes at the corresponding pixel becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated pixel 12 on the right in FIG. 1. The behavior is the same regardless of the polarity of the applied potential difference. Though a series of pixels in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

FIG. 2 shows an example of a system block diagram illustrating an electronic device incorporating a 3×3 interferometric modulator display. The electronic device includes a processor 21 that may be configured to execute one or more software modules. In addition to executing an operating system, the processor 21 may be configured to execute one or more software applications, including a web browser, a telephone application, an email program, or any other software application.

The processor 21 can be configured to communicate with an array driver 22. The array driver 22 can include a row driver circuit 24 and a column driver circuit 26 that provide signals to, e.g., a display array or panel 30. The cross section of the IMOD display device illustrated in FIG. 1 is shown by the lines 1-1 in FIG. 2. Although FIG. 2 illustrates a 3×3 array of IMODs for the sake of clarity, the display array 30 may contain a very large number of IMODs, and may have a different number of IMODs in rows than in columns, and vice versa.

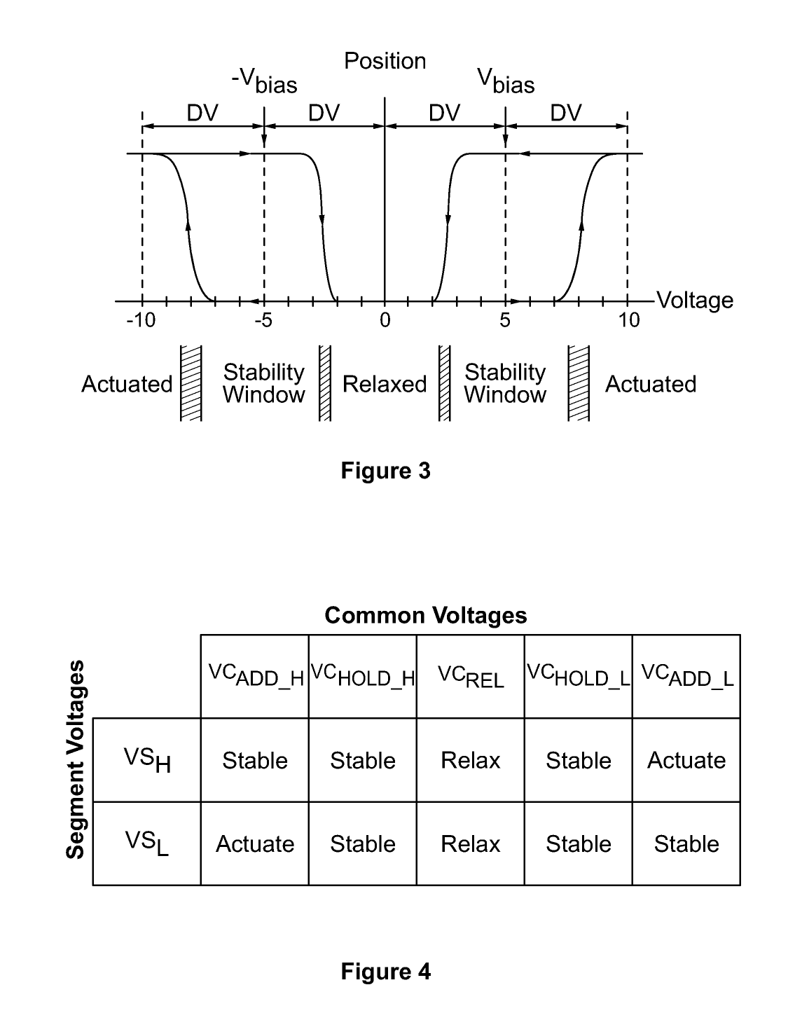

FIG. 3 shows an example of a diagram illustrating movable reflective layer position versus applied voltage for the interferometric modulator of FIG. 1. For MEMS interferometric modulators, the row/column (i.e., common/segment) write procedure may take advantage of a hysteresis property of these devices as illustrated in FIG. 3. An interferometric modulator may require, for example, about a 10-volt potential difference to cause the movable reflective layer, or mirror, to change from the relaxed state to the actuated state. When the voltage is reduced from that value, the movable reflective layer maintains its state as the voltage drops back below, e.g., 10-volts, however, the movable reflective layer does not relax completely until the voltage drops below 2-volts. Thus, a range of voltage, approximately 3 to 7-volts, as shown in FIG. 3, exists where there is a window of applied voltage within which the device is stable in either the relaxed or actuated state. This is referred to herein as the “hysteresis window” or “stability window.” For a display array 30 having the hysteresis characteristics of FIG. 3, the row/column write procedure can be designed to address one or more rows at a time, such that during the addressing of a given row, pixels in the addressed row that are to be actuated are exposed to a voltage difference of about 10-volts, and pixels that are to be relaxed are exposed to a voltage difference of near zero volts. After addressing, the pixels are exposed to a steady state or bias voltage difference of approximately 5-volts such that they remain in the previous strobing state. In this example, after being addressed, each pixel sees a potential difference within the “stability window” of about 3-7-volts. This hysteresis property feature enables the pixel design, e.g., illustrated in FIG. 1, to remain stable in either an actuated or relaxed pre-existing state under the same applied voltage conditions. Since each IMOD pixel, whether in the actuated or relaxed state, is essentially a capacitor formed by the fixed and moving reflective layers, this stable state can be held at a steady voltage within the hysteresis window without substantially consuming or losing power. Moreover, essentially little or no current flows into the IMOD pixel if the applied voltage potential remains substantially fixed.

In some implementations, a frame of an image may be created by applying data signals in the form of “segment” voltages along the set of column electrodes, in accordance with the desired change (if any) to the state of the pixels in a given row. Each row of the array can be addressed in turn, such that the frame is written one row at a time. To write the desired data to the pixels in a first row, segment voltages corresponding to the desired state of the pixels in the first row can be applied on the column electrodes, and a first row pulse in the form of a specific “common” voltage or signal can be applied to the first row electrode. The set of segment voltages can then be changed to correspond to the desired change (if any) to the state of the pixels in the second row, and a second common voltage can be applied to the second row electrode. In some implementations, the pixels in the first row are unaffected by the change in the segment voltages applied along the column electrodes, and remain in the state they were set to during the first common voltage row pulse. This process may be repeated for the entire series of rows, or alternatively, columns, in a sequential fashion to produce the image frame. The frames can be refreshed and/or updated with new image data by continually repeating this process at some desired number of frames per second.

The combination of segment and common signals applied across each pixel (that is, the potential difference across each pixel) determines the resulting state of each pixel. FIG. 4 shows an example of a table illustrating various states of an interferometric modulator when various common and segment voltages are applied. As will be readily understood by one having ordinary skill in the art, the “segment” voltages can be applied to either the column electrodes or the row electrodes, and the “common” voltages can be applied to the other of the column electrodes or the row electrodes.

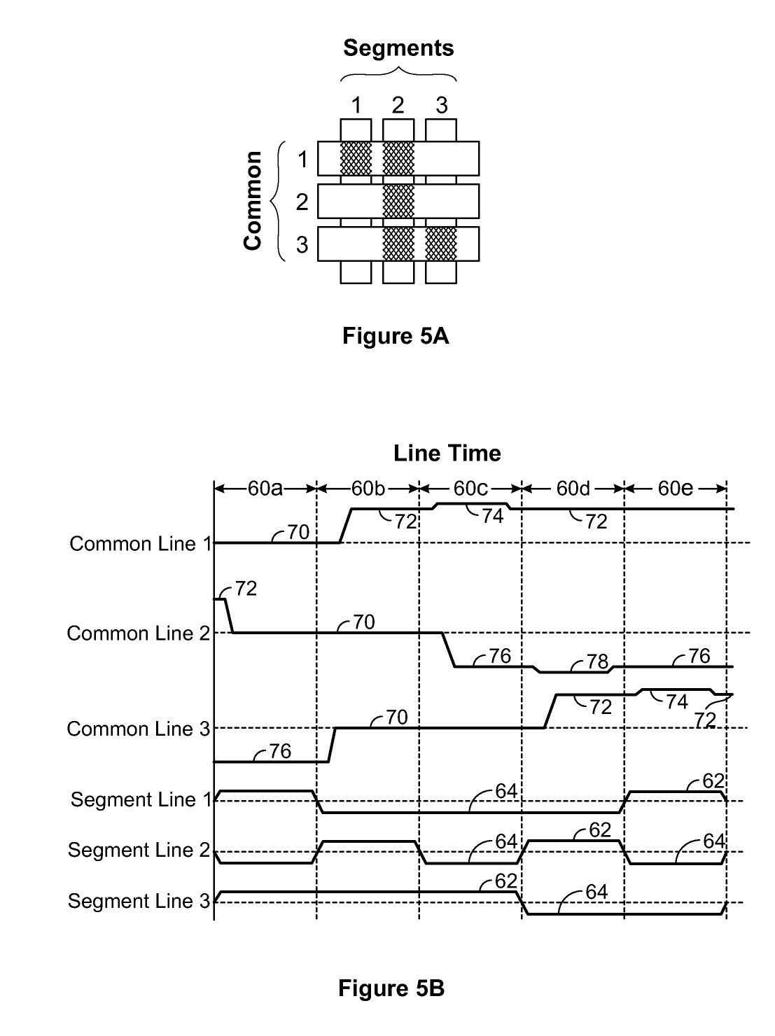

As illustrated in FIG. 4 (as well as in the timing diagram shown in FIG. 5B), when a release voltage VC_{REL} is applied along a common line, all interferometric modulator elements along the common line will be placed in a relaxed state, alternatively referred to as a released or unactuated state, regardless of the voltage applied along the segment lines, i.e., high segment voltage VS_{H} and low segment voltage VS_{L}. In particular, when the release voltage VC_{REL} is applied along a common line, the potential voltage across the modulator (alternatively referred to as a pixel voltage) is within the relaxation window (see FIG. 3, also referred to as a release window) both when the high segment voltage VS_{H} and the low segment voltage VS_{L} are applied along the corresponding segment line for that pixel.

When a hold voltage is applied on a common line, such as a high hold voltage VC_{HOLD}_{_{—}}_{H} or a low hold voltage VC_{HOLD}_{_{—}}_{L}, the state of the interferometric modulator will remain constant. For example, a relaxed IMOD will remain in a relaxed position, and an actuated IMOD will remain in an actuated position. The hold voltages can be selected such that the pixel voltage will remain within a stability window both when the high segment voltage VS_{H} and the low segment voltage VS_{L} are applied along the corresponding segment line. Thus, the segment voltage swing, i.e., the difference between the high VS_{H} and low segment voltage VS_{L}, is less than the width of either the positive or the negative stability window.

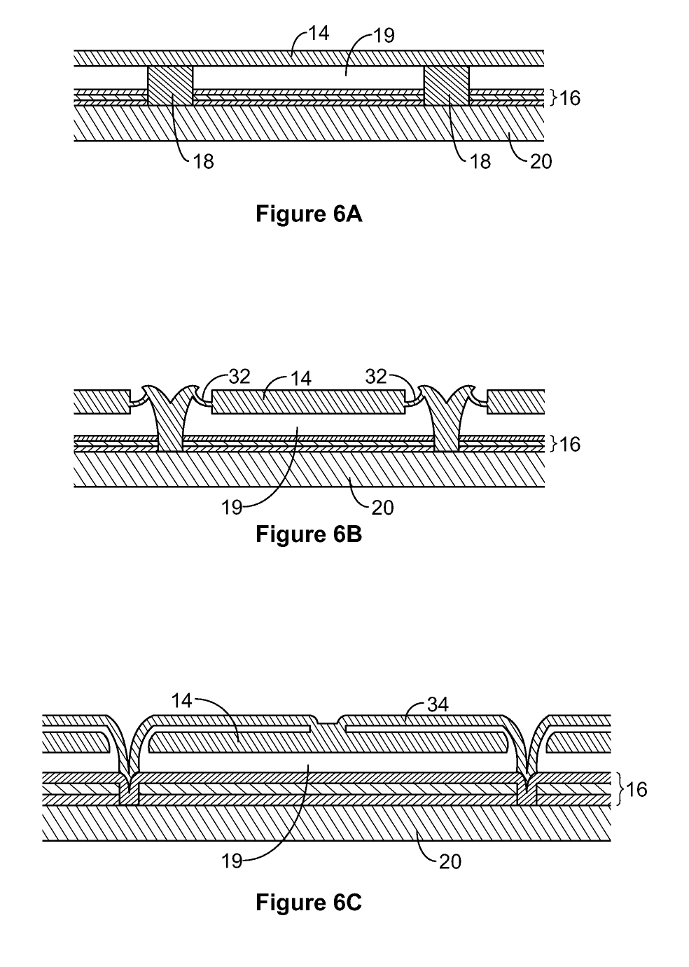

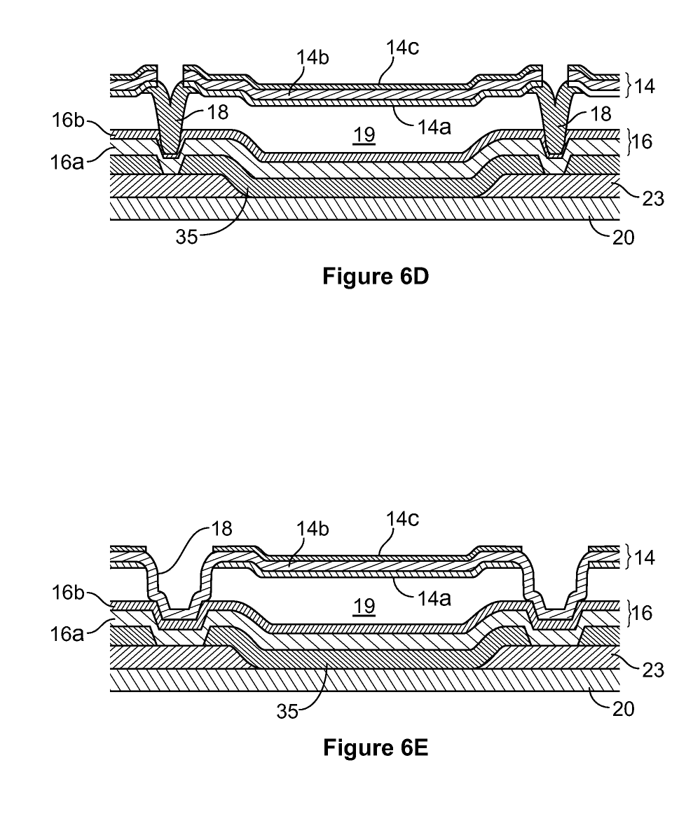

FIGS. 6A and 6B are system block diagrams illustrating an embodiment of a display device 40. The display device 40 can be, for example, a cellular or mobile telephone. However, the same components of display device 40 or slight variations thereof are also illustrative of various types of display devices such as televisions, e-readers and portable media players.

When an addressing, or actuation, voltage is applied on a common line, such as a high addressing voltage VC_{ADD}_{_{—}}_{H} or a low addressing voltage VC_{ADD}_{_{—}}_{L}, data can be selectively written to the modulators along that line by application of segment voltages along the respective segment lines. The segment voltages may be selected such that actuation is dependent upon the segment voltage applied. When an addressing voltage is applied along a common line, application of one segment voltage will result in a pixel voltage within a stability window, causing the pixel to remain unactuated. In contrast, application of the other segment voltage will result in a pixel voltage beyond the stability window, resulting in actuation of the pixel. The particular segment voltage which causes actuation can vary depending upon which addressing voltage is used. In some implementations, when the high addressing voltage VC_{ADD}_{_{—}}_{H} is applied along the common line, application of the high segment voltage VS_{H} can cause a modulator to remain in its current position, while application of the low segment voltage VS_{L} can cause actuation of the modulator. As a corollary, the effect of the segment voltages can be the opposite when a low addressing voltage VC_{ADD}_{_{—}}_{L} is applied, with high segment voltage VS_{H} causing actuation of the modulator, and low segment voltage VS_{L} having no effect (i.e., remaining stable) on the state of the modulator.

In some implementations, hold voltages, address voltages, and segment voltages may be used which always produce the same polarity potential difference across the modulators. In some other implementations, signals can be used which alternate the polarity of the potential difference of the modulators. Alternation of the polarity across the modulators (that is, alternation of the polarity of write procedures) may reduce or inhibit charge accumulation which could occur after repeated write operations of a single polarity.

FIG. 5A shows an example of a diagram illustrating a frame of display data in the 3×3 interferometric modulator display of FIG. 2. FIG. 5B shows an example of a timing diagram for common and segment signals that may be used to write the frame of display data illustrated in FIG. 5A. The signals can be applied to the, e.g., 3×3 array of FIG. 2, which will ultimately result in the line time 60e display arrangement illustrated in FIG. 5A. The actuated modulators in FIG. 5A are in a dark-state, i.e., where a substantial portion of the reflected light is outside of the visible spectrum so as to result in a dark appearance to, e.g., a viewer. Prior to writing the frame illustrated in FIG. 5A, the pixels can be in any state, but the write procedure illustrated in the timing diagram of FIG. 5B presumes that each modulator has been released and resides in an unactuated state before the first line time 60a.

During the first line time 60a: a release voltage 70 is applied on common line 1; the voltage applied on common line 2 begins at a high hold voltage 72 and moves to a release voltage 70; and a low hold voltage 76 is applied along common line 3. Thus, the modulators (common 1, segment 1), (1,2) and (1,3) along common line 1 remain in a relaxed, or unactuated, state for the duration of the first line time 60a, the modulators (2,1), (2,2) and (2,3) along common line 2 will move to a relaxed state, and the modulators (3,1), (3,2) and (3,3) along common line 3 will remain in their previous state. With reference to FIG. 4, the segment voltages applied along segment lines 1, 2 and 3 will have no effect on the state of the interferometric modulators, as none of common lines 1, 2 or 3 are being exposed to voltage levels causing actuation during line time 60a (i.e., VC_{REL}-relax and VC_{HOLD}_{_{—}}_{L}-stable).

During the second line time 60b, the voltage on common line 1 moves to a high hold voltage 72, and all modulators along common line 1 remain in a relaxed state regardless of the segment voltage applied because no addressing, or actuation, voltage was applied on the common line 1. The modulators along common line 2 remain in a relaxed state due to the application of the release voltage 70, and the modulators (3,1), (3,2) and (3,3) along common line 3 will relax when the voltage along common line 3 moves to a release voltage 70.

During the third line time 60c, common line 1 is addressed by applying a high address voltage 74 on common line 1. Because a low segment voltage 64 is applied along segment lines 1 and 2 during the application of this address voltage, the pixel voltage across modulators (1,1) and (1,2) is greater than the high end of the positive stability window (i.e., the voltage differential exceeded a predefined threshold) of the modulators, and the modulators (1,1) and (1,2) are actuated. Conversely, because a high segment voltage 62 is applied along segment line 3, the pixel voltage across modulator (1,3) is less than that of modulators (1,1) and (1,2), and remains within the positive stability window of the modulator; modulator (1,3) thus remains relaxed. Also during line time 60c, the voltage along common line 2 decreases to a low hold voltage 76, and the voltage along common line 3 remains at a release voltage 70, leaving the modulators along common lines 2 and 3 in a relaxed position.

During the fourth line time 60d, the voltage on common line 1 returns to a high hold voltage 72, leaving the modulators along common line 1 in their respective addressed states. The voltage on common line 2 is decreased to a low address voltage 78. Because a high segment voltage 62 is applied along segment line 2, the pixel voltage across modulator (2,2) is below the lower end of the negative stability window of the modulator, causing the modulator (2,2) to actuate. Conversely, because a low segment voltage 64 is applied along segment lines 1 and 3, the modulators (2,1) and (2,3) remain in a relaxed position. The voltage on common line 3 increases to a high hold voltage 72, leaving the modulators along common line 3 in a relaxed state.

Finally, during the fifth line time 60e, the voltage on common line 1 remains at high hold voltage 72, and the voltage on common line 2 remains at a low hold voltage 76, leaving the modulators along common lines 1 and 2 in their respective addressed states. The voltage on common line 3 increases to a high address voltage 74 to address the modulators along common line 3. As a low segment voltage 64 is applied on segment lines 2 and 3, the modulators (3,2) and (3,3) actuate, while the high segment voltage 62 applied along segment line 1 causes modulator (3,1) to remain in a relaxed position. Thus, at the end of the fifth line time 60e, the 3×3 pixel array is in the state shown in FIG. 5A, and will remain in that state as long as the hold voltages are applied along the common lines, regardless of variations in the segment voltage which may occur when modulators along other common lines (not shown) are being addressed.

In the timing diagram of FIG. 5B, a given write procedure (i.e., line times 60a-60e) can include the use of either high hold and address voltages, or low hold and address voltages. Once the write procedure has been completed for a given common line (and the common voltage is set to the hold voltage having the same polarity as the actuation voltage), the pixel voltage remains within a given stability window, and does not pass through the relaxation window until a release voltage is applied on that common line. Furthermore, as each modulator is released as part of the write procedure prior to addressing the modulator, the actuation time of a modulator, rather than the release time, may determine the necessary line time. Specifically, in implementations in which the release time of a modulator is greater than the actuation time, the release voltage may be applied for longer than a single line time, as depicted in FIG. 5B. In some other implementations, voltages applied along common lines or segment lines may vary to account for variations in the actuation and release voltages of different modulators, such as modulators of different colors.

The details of the structure of interferometric modulators that operate in accordance with the principles set forth above may vary widely. For example, FIGS. 6A-6E show examples of cross-sections of varying implementations of interferometric modulators, including the movable reflective layer 14 and its supporting structures. FIG. 6A shows an example of a partial cross-section of the interferometric modulator display of FIG. 1, where a strip of metal material, i.e., the movable reflective layer 14 is deposited on supports 18 extending orthogonally from the substrate 20. In FIG. 6B, the movable reflective layer 14 of each IMOD is generally square or rectangular in shape and attached to supports at or near the corners, on tethers 32. In FIG. 6C, the movable reflective layer 14 is generally square or rectangular in shape and suspended from a deformable layer 34, which may include a flexible metal. The deformable layer 34 can connect, directly or indirectly, to the substrate 20 around the perimeter of the movable reflective layer 14. These connections are herein referred to as support posts. The implementation shown in FIG. 6C has additional benefits deriving from the decoupling of the optical functions of the movable reflective layer 14 from its mechanical functions, which are carried out by the deformable layer 34. This decoupling allows the structural design and materials used for the reflective layer 14 and those used for the deformable layer 34 to be optimized independently of one another.

FIG. 6D shows another example of an IMOD, where the movable reflective layer 14 includes a reflective sub-layer 14a. The movable reflective layer 14 rests on a support structure, such as support posts 18. The support posts 18 provide separation of the movable reflective layer 14 from the lower stationary electrode (i.e., part of the optical stack 16 in the illustrated IMOD) so that a gap 19 is formed between the movable reflective layer 14 and the optical stack 16, for example when the movable reflective layer 14 is in a relaxed position. The movable reflective layer 14 also can include a conductive layer 14c, which may be configured to serve as an electrode, and a support layer 14b. In this example, the conductive layer 14c is disposed on one side of the support layer 14b, distal from the substrate 20, and the reflective sub-layer 14a is disposed on the other side of the support layer 14b, proximal to the substrate 20. In some implementations, the reflective sub-layer 14a can be conductive and can be disposed between the support layer 14b and the optical stack 16. The support layer 14b can include one or more layers of a dielectric material, for example, silicon oxynitride (SiON) or silicon dioxide (SiO₂). In some implementations, the support layer 14b can be a stack of layers, such as, for example, a SiO₂/SiON/SiO₂ tri-layer stack. Either or both of the reflective sub-layer 14a and the conductive layer 14c can include, e.g., an Al alloy with about 0.5% Cu, or another reflective metallic material. Employing conductive layers 14a, 14c above and below the dielectric support layer 14b can balance stresses and provide enhanced conduction. In some implementations, the reflective sub-layer 14a and the conductive layer 14c can be formed of different materials for a variety of design purposes, such as achieving specific stress profiles within the movable reflective layer 14.

As illustrated in FIG. 6D, some implementations also can include a black mask structure 23. The black mask structure 23 can be formed in optically inactive regions (e.g., between pixels or under posts 18) to absorb ambient or stray light. The black mask structure 23 also can improve the optical properties of a display device by inhibiting light from being reflected from or transmitted through inactive portions of the display, thereby increasing the contrast ratio. Additionally, the black mask structure 23 can be conductive and be configured to function as an electrical bussing layer. In some implementations, the row electrodes can be connected to the black mask structure 23 to reduce the resistance of the connected row electrode. The black mask structure 23 can be formed using a variety of methods, including deposition and patterning techniques. The black mask structure 23 can include one or more layers. For example, in some implementations, the black mask structure 23 includes a molybdenum-chromium (MoCr) layer that serves as an optical absorber, a SiO₂ layer, and an aluminum alloy that serves as a reflector and a bussing layer, with a thickness in the range of about 30-80 Å, 500-1000 Å, and 500-6000 Å, respectively. The one or more layers can be patterned using a variety of techniques, including photolithography and dry etching, including, for example, CF₄ and/or O₂ for the MoCr and SiO₂ layers and Cl₂ and/or BCl₃ for the aluminum alloy layer. In some implementations, the black mask 23 can be an etalon or interferometric stack structure. In such interferometric stack black mask structures 23, the conductive absorbers can be used to transmit or bus signals between lower, stationary electrodes in the optical stack 16 of each row or column. In some implementations, a spacer layer 35 can serve to generally electrically isolate the absorber layer 16a from the conductive layers in the black mask 23.

FIG. 6E shows another example of an IMOD, where the movable reflective layer 14 is self supporting. In contrast with FIG. 6D, the implementation of FIG. 6E does not include support posts 18. Instead, the movable reflective layer 14 contacts the underlying optical stack 16 at multiple locations, and the curvature of the movable reflective layer 14 provides sufficient support that the movable reflective layer 14 returns to the unactuated position of FIG. 6E when the voltage across the interferometric modulator is insufficient to cause actuation. The optical stack 16, which may contain a plurality of several different layers, is shown here for clarity including an optical absorber 16a, and a dielectric 16b. In some implementations, the optical absorber 16a may serve both as a fixed electrode and as a partially reflective layer.

In implementations such as those shown in FIGS. 6A-6E, the IMODs function as direct-view devices, in which images are viewed from the front side of the transparent substrate 20, i.e., the side opposite to that upon which the modulator is arranged. In these implementations, the back portions of the device (that is, any portion of the display device behind the movable reflective layer 14, including, for example, the deformable layer 34 illustrated in FIG. 6C) can be configured and operated upon without impacting or negatively affecting the image quality of the display device, because the reflective layer 14 optically shields those portions of the device. For example, in some implementations a bus structure (not illustrated) can be included behind the movable reflective layer 14 which provides the ability to separate the optical properties of the modulator from the electromechanical properties of the modulator, such as voltage addressing and the movements that result from such addressing. Additionally, the implementations of FIGS. 6A-6E can simplify processing, such as, e.g., patterning.

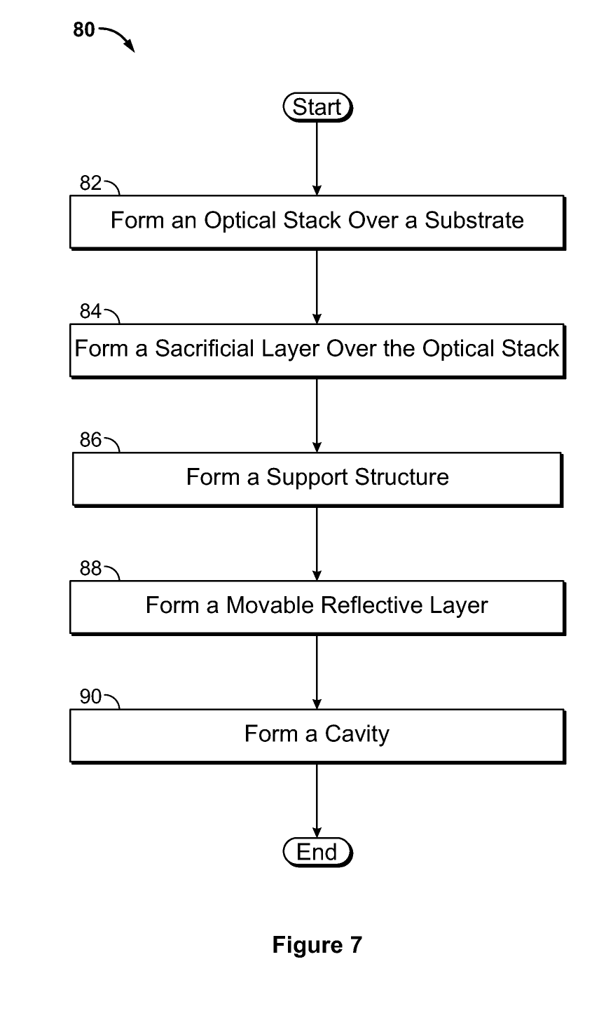

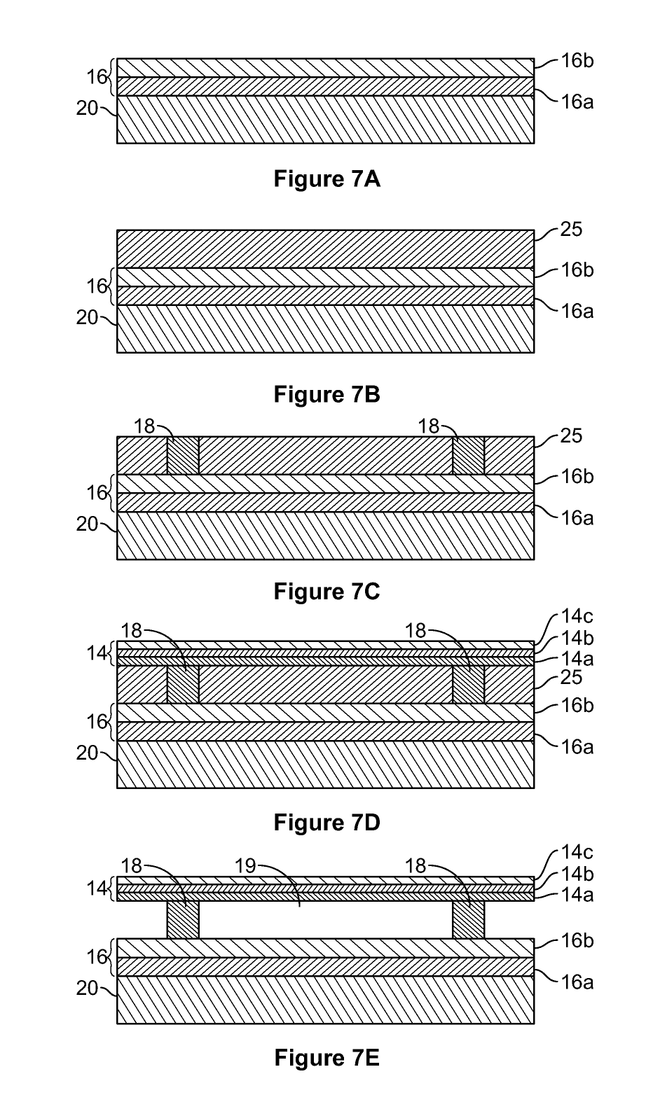

FIG. 7 shows an example of a flow diagram illustrating a manufacturing process 80 for an interferometric modulator, and FIGS. 7A-7E show examples of cross-sectional schematic illustrations of corresponding stages of such a manufacturing process 80. In some implementations, the manufacturing process 80 can be implemented to manufacture, e.g., interferometric modulators of the general type illustrated in FIGS. 1 and 6, in addition to other blocks not shown in FIG. 7. With reference to FIGS. 1, 6 and 7, the process 80 begins at block 82 with the formation of the optical stack 16 over the substrate 20. FIG. 7A illustrates such an optical stack 16 formed over the substrate 20. The substrate 20 may be a transparent substrate such as glass or plastic, it may be flexible or relatively stiff and unbending, and may have been subjected to prior preparation processes, e.g., cleaning, to facilitate efficient formation of the optical stack 16. As discussed above, the optical stack 16 can be electrically conductive, partially transparent and partially reflective and may be fabricated, for example, by depositing one or more layers having the desired properties onto the transparent substrate 20. In FIG. 7A, the optical stack 16 includes a multilayer structure having sub-layers 16a and 16b, although more or fewer sub-layers may be included in some other implementations. In some implementations, one of the sub-layers 16a, 16b can be configured with both optically absorptive and conductive properties, such as the combined conductor/absorber sub-layer 16a. Additionally, one or more of the sub-layers 16a, 16b can be patterned into parallel strips, and may form row electrodes in a display device. Such patterning can be performed by a masking and etching process or another suitable process known in the art. In some implementations, one of the sub-layers 16a, 16b can be an insulating or dielectric layer, such as sub-layer 16b that is deposited over one or more metal layers (e.g., one or more reflective and/or conductive layers). In addition, the optical stack 16 can be patterned into individual and parallel strips that form the rows of the display.

The process 80 continues at block 84 with the formation of a sacrificial layer 25 over the optical stack 16. The sacrificial layer 25 is later removed (e.g., at block 90) to form the cavity 19 and thus the sacrificial layer 25 is not shown in the resulting interferometric modulators 12 illustrated in FIG. 1. FIG. 7B illustrates a partially fabricated device including a sacrificial layer 25 formed over the optical stack 16. The formation of the sacrificial layer 25 over the optical stack 16 may include deposition of a xenon difluoride (XeF₂)-etchable material such as molybdenum (Mo) or amorphous silicon (Si), in a thickness selected to provide, after subsequent removal, a gap or cavity 19 (see also FIGS. 1 and 7E) having a desired design size. Deposition of the sacrificial material may be carried out using deposition techniques such as physical vapor deposition (PVD, e.g., sputtering), plasma-enhanced chemical vapor deposition (PECVD), thermal chemical vapor deposition (thermal CVD), or spin-coating.

The process 80 continues at block 86 with the formation of a support structure e.g., a post 18 as illustrated in FIGS. 1, 6 and 7C. The formation of the post 18 may include patterning the sacrificial layer 25 to form a support structure aperture, then depositing a material (e.g., a polymer or an inorganic material, e.g., silicon oxide) into the aperture to form the post 18, using a deposition method such as PVD, PECVD, thermal CVD, or spin-coating. In some implementations, the support structure aperture formed in the sacrificial layer can extend through both the sacrificial layer 25 and the optical stack 16 to the underlying substrate 20, so that the lower end of the post 18 contacts the substrate 20 as illustrated in FIG. 6A. Alternatively, as depicted in FIG. 7C, the aperture formed in the sacrificial layer 25 can extend through the sacrificial layer 25, but not through the optical stack 16. For example, FIG. 7E illustrates the lower ends of the support posts 18 in contact with an upper surface of the optical stack 16. The post 18, or other support structures, may be formed by depositing a layer of support structure material over the sacrificial layer 25 and patterning portions of the support structure material located away from apertures in the sacrificial layer 25. The support structures may be located within the apertures, as illustrated in FIG. 7C, but also can, at least partially, extend over a portion of the sacrificial layer 25. As noted above, the patterning of the sacrificial layer 25 and/or the support posts 18 can be performed by a patterning and etching process, but also may be performed by alternative etching methods.

The process 80 continues at block 88 with the formation of a movable reflective layer or membrane such as the movable reflective layer 14 illustrated in FIGS. 1, 6 and 7D. The movable reflective layer 14 may be formed by employing one or more deposition steps, e.g., reflective layer (e.g., aluminum, aluminum alloy) deposition, along with one or more patterning, masking, and/or etching steps. The movable reflective layer 14 can be electrically conductive, and referred to as an electrically conductive layer. In some implementations, the movable reflective layer 14 may include a plurality of sub-layers 14a, 14b, 14c as shown in FIG. 7D. In some implementations, one or more of the sub-layers, such as sub-layers 14a, 14c, may include highly reflective sub-layers selected for their optical properties, and another sub-layer 14b may include a mechanical sub-layer selected for its mechanical properties. Since the sacrificial layer 25 is still present in the partially fabricated interferometric modulator formed at block 88, the movable reflective layer 14 is typically not movable at this stage. A partially fabricated IMOD that contains a sacrificial layer 25 may also be referred to herein as an “unreleased” IMOD. As described above in connection with FIG. 1, the movable reflective layer 14 can be patterned into individual and parallel strips that form the columns of the display.

The process 80 continues at block 90 with the formation of a cavity, e.g., cavity 19 as illustrated in FIGS. 1, 6 and 7E. The cavity 19 may be formed by exposing the sacrificial material 25 (deposited at block 84) to an etchant. For example, an etchable sacrificial material such as Mo or amorphous Si may be removed by dry chemical etching, e.g., by exposing the sacrificial layer 25 to a gaseous or vaporous etchant, such as vapors derived from solid XeF₂ for a period of time that is effective to remove the desired amount of material, typically selectively removed relative to the structures surrounding the cavity 19. Other etching methods, e.g. wet etching and/or plasma etching, also may be used. Since the sacrificial layer 25 is removed during block 90, the movable reflective layer 14 is typically movable after this stage. After removal of the sacrificial material 25, the resulting fully or partially fabricated IMOD may be referred to herein as a “released” IMOD.

Interferometric modulator (IMOD) display systems typically involve arrays of electromechanical devices, in which each electromechanical device has three different air gap sizes representing three different colors (e.g., red-green-blue for RGB displays) or shades (e.g., grayscale). For example, each electromechanical device represents a pixel in a color display, where each pixel typically includes three IMOD types or subpixels. Hereinafter, certain examples of implementations will be described for different interferometric electromechanical architectures.

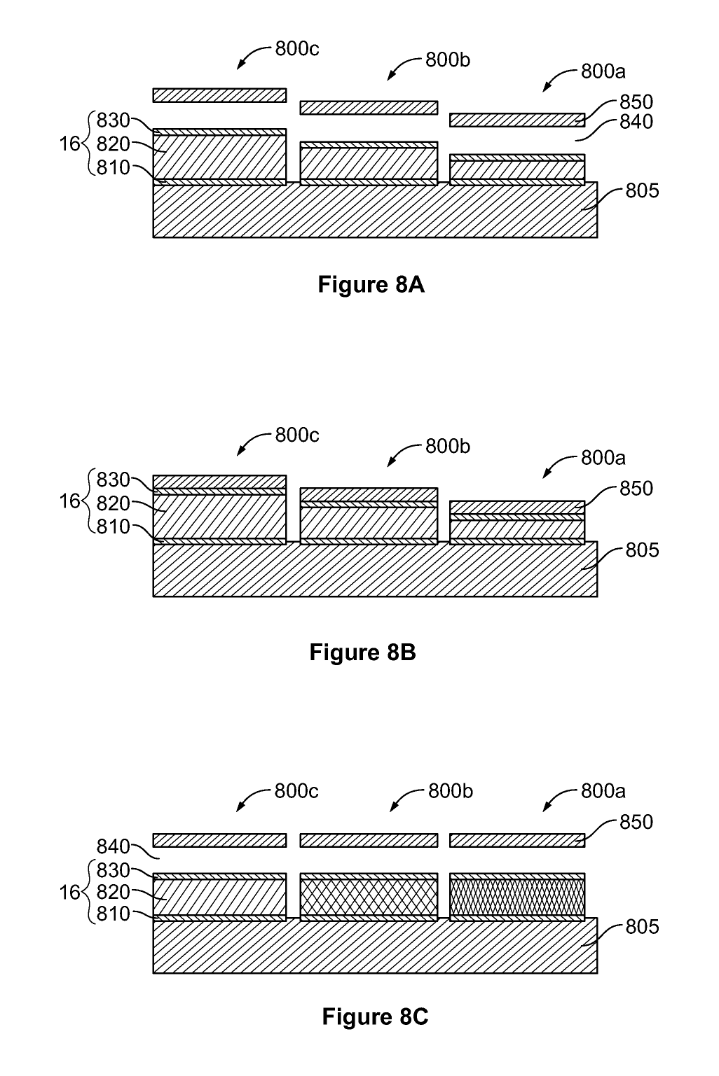

FIG. 8A shows an example of a schematic cross section of an implementation of three different interferometric modulators, corresponding to three different colors, with all three shown in the open state having a constant air gap and three different dielectric thicknesses. FIG. 8A illustrates the device in the open state, while FIG. 8B illustrates the device in the closed state. While it is possible for electromechanical devices to have more than two states with differing gap sizes in the different states, the presently described implementations assume two-state devices, fully open or fully closed, such that references to “gap size” herein refer to maximum gap size in the fully open state.

FIG. 8A illustrates an electromechanical system device including a substrate 805 on which at least three different types of IMOD structures 800a, 800b and 800c are formed. Each of the at least three different types of IMOD structures 800a, 800b and 800c are configured to reflect a different color in one of the states. The different IMOD structures 800a, 800b and 800c include an optical stack 16, an air gap 840, and a movable reflective layer 850. In the illustrated implementation, the optical stack 16 is formed on the substrate 805. One having ordinary skill in the art will readily understand that the figures are simplified schematics and additional layers, such as underlying or intervening buffer layers, black mask layers, and bussing layers, may be present. The optical stack 16 may include an optical absorber layer 810 and a transparent solid layer 820 formed over the absorber layer 810. The transparent solid layer 820 can be a dielectric layer. In some implementations, the optical stack 16 may further include a second absorber layer 830 formed over the transparent solid layer 820. In addition, the optical stack 16 may further include a transparent conductor layer (not shown), such as ITO. The IMOD structures 800a, 800b and 800c can be configured with the movable reflective layer 850 above the second absorber layer 830, and also can include the air gap 840 formed between the reflective layer 850 and the second absorber layer 830. Optical absorbers are typically semitransparent metallic or semiconductor layers such as molybdenum (Mo), chromium (Cr), silicon (Si), germanium (Ge), or mixtures thereof.

The movable reflector 850 can serve as the moving or upper electrode for the electromechanical device, and can take any of a number of forms (see, e.g., FIGS. 7A-7F). The optical stack 16 includes conductor(s) and serves as the stationary or lower electrode of the electromechanical device.

In FIG. 8A, the electromechanical system device includes three IMOD structures 800a, 800b and 800c each having the same constant or uniform air gap 840. The air gap 840 is formed by depositing a single thickness of sacrificial material between the upper and lower electrodes, and subsequent removal of the sacrificial material from between the electrodes by “release” etching. A vapor phase etchant for the release can be a fluorine-based etchant, such as xenon difluoride (XeF₂), fluorine (F₂), or hydrogen fluoride (HF), and the sacrificial layer may be formed, e.g., of molybdenum, (Mo), amorphous Si, tungsten (W), or titanium (Ti) for selective removal by F-based etchants relative to surrounding structural materials.

The constant or uniform air gap 840 can reduce the complexity of fabricating IMOD structures by requiring the deposition of only a single sacrificial layer. Typically, IMOD structures used multiple sacrificial layers with different thicknesses and/or complex masking sequences to produce multiple air gap sizes. Some exemplary methods of fabricating air gaps of different sizes are described in U.S. Pat. No. 7,297,471 and U.S. Pat. Pub. No. 2007/0269748. Because producing air gap layers of different sizes can require multiple depositions, multiple masks, and multiple etching, one having ordinary skill in the art will readily recognize that simultaneous release etching of multiple thicknesses of the same material gives rise to etch attack issues and etch-related non-uniformity in the air gaps, in addition to etch damage during multiple patterning processes to form the different thicknesses. In contrast to the illustrated implementations, when multiple thicknesses of sacrificial material are employed, during removal or “release etching” the thinner sacrificial layers are removed first after which, while the thicker sacrificial layers are still being removed, permanent structures exposed by removal of the thinner sacrificial layers are subjected to prolonged exposure to the etchants. Such etchants typically exhibit less than perfect etch selectivity, such that the prolonged exposure can cause damage to permanent structures in the IMODs with smaller gap sizes. However, a single sacrificial layer for a single air gap can be made using only one deposition and one mask, which thereby eliminates the aforementioned problems. Furthermore, fewer depositions, fewer masks, and reduced material consumption may ultimately reduce the cost and improve efficiency of fabricating IMOD structures.

FIG. 8A also illustrates an electromechanical system device including three IMOD structures 800a, 800b and 800c having different transparent solid layer 820 thicknesses. The transparent solid layer 820 can include a dielectric material such as SiO₂ or another substantially transparent material like SiOₓN_{y}, Al₂O₃, TiO₂, ZrO₂, HfO₂, In₂O₃, SnO₂, ZnO, SiN, or mixtures thereof. In some implementations, the transparent solid layer 820 may be about 1000 Angstroms (Å) to 8000 Å in thickness.

The transparent solid layer 820 can be configured to include the same material but having different thicknesses so that incident light travels different optical path lengths for each one of the three IMOD structures 800a, 800b and 800c. For example, optical path length is the product of the distance the light travels multiplied by the index of refraction of the material through which the light travels. When light hits the structure, there can be constructive interference of a particular wavelength depending on the optical path length. In one example, in which the IMOD structures are configured to reflect color in the closed state and transparent solid layers 820 are made of SiO₂ having an index of refraction of about 1.46, one of the IMODs (structure 800a) can be configured to reflect blue light (e.g., λ˜450 nm) having a dielectric thickness of about 1360 Å; one (structure 800b) configured to reflect green light (e.g., λ˜550 nm) having a dielectric thickness of about 1720 Å; and the third (structure 800c) configured to reflect red light (e.g., λ˜630 nm) having a dielectric thickness of about 2000 Å.

The electromechanical system device also can include a first absorber layer 810 that is configured to partially absorb incident light. In some implementations, the electromechanical system device also includes a second absorber layer 830 formed between the transparent solid layer 820 and the air gap 840. The electromechanical system may further include a very thin dielectric passivation layer (not shown) over the second absorber layer 830 to insulate the moving layer 850 from the second absorber layer 830 in the collapsed state. The absorber layer 810 is partially transparent and may include 10 Å to 80 Å of a metallic or semiconductor film, such as Mo, Cr, Si, Ge, or alloys thereof. In general, the absorber layer 810 includes a metallic material having a semi-reflective thickness. The thickness of the absorber layer 810 is less than the material's “skin depth” at optical frequencies, defined as the depth from the surface of a material at which the electromagnetic fields decay to 1/e from the surface of the material. Skin depth varies according to the inverse of conductivity, which means that better conductors have a lower skin depth. In one implementation, both the absorber layers 810 and 830 include MoCr having a thickness of approximately 25 Å each. In some implementations, the thickness and material composition of the absorber layers 810 and 830 can affect the reflected color purity, specifically color hue and saturation.

Another aspect of using two absorber layers 810 and 830 is the ability to reflect a substantially similar or common color appearance such as dark (or white) when the IMOD structures 800a, 800b and 800c are in an open or relaxed state with a common gap size, as illustrated in FIG. 8A, and to reflect different colors or shades when the IMOD structures 800a, 800b and 800c are in a closed or collapsed state, as illustrated in FIG. 8B. When a voltage is applied to an IMOD structure, the movable reflective layer 850 is electrostatically displaced toward the optical stack 16, altering the distance between the movable reflective layer 850 and the optical stack 16. This enables the IMOD structure to actuate between an open and closed state. Typical color IMOD arrays accomplish a common background appearance (e.g., black or white) in the closed condition because identical optical stacks define the optical paths when the various different IMODs are closed, whereas in the open state, the IMOD structure reflects different colors or shades depending on the different gap sizes. In some implementations, employing common open gap sizes and differing optical stacks can present a challenge in obtaining a common background state, since the optical path lengths differ for the different IMOD types in both open and closed states. However, having two absorber layers 810 and 830 can allow the closed state to reflect different colors, and the open state to reflect a common dark (or white) appearance.

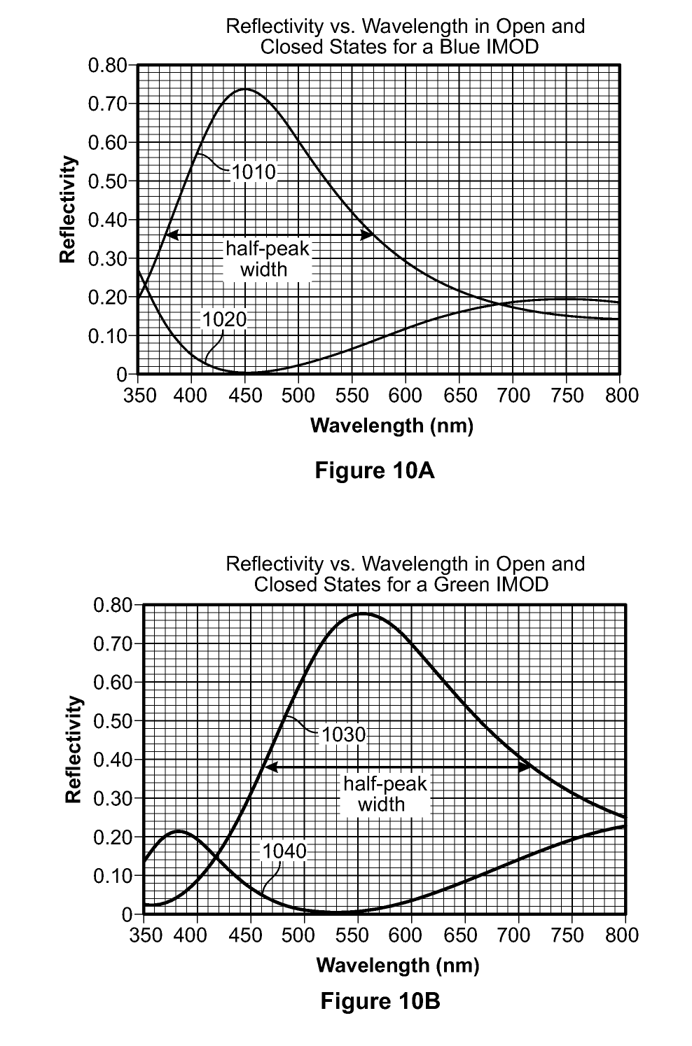

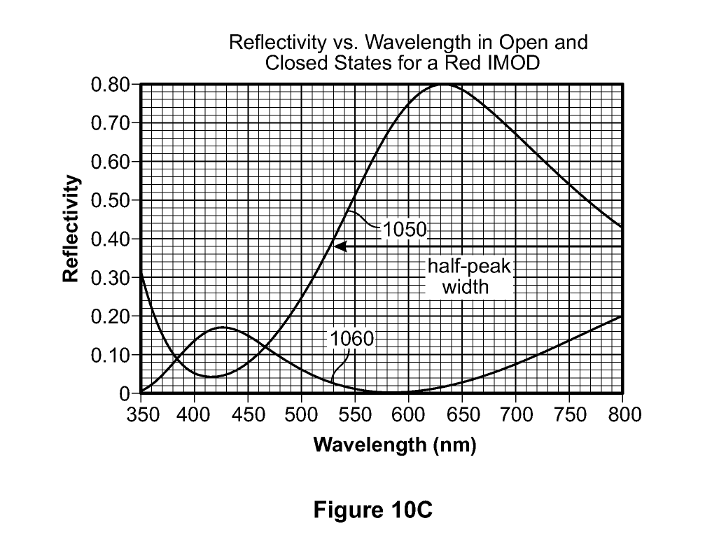

FIG. 8A illustrates the electromechanical system device in the open or relaxed state. A person having ordinary skill in the art will appreciate that because transparent solid layer 820 includes three different thicknesses for each IMOD structure 800a, 800b and 800c corresponding to three different optical path lengths, it is difficult to configure all three IMOD structures 800a, 800b and 800c to have an optical path length to reflect a black state using only the path length defined by the three layers 820 and gaps 840. In some implementations, to overcome this difficulty, a second absorber layer 830 can be added to the device so that incident light is substantially absorbed for each of the three IMOD structures 800a, 800b and 800c in the open state despite the light traveling different optical path lengths. Nevertheless, with different optical path lengths, each IMOD structure can still reflect different spectrums representing varying degrees of dark (see FIGS. 10A-10C and attendant description). Sufficiency of darkness in the open state can be determined by contrast ratio, which is the ratio between the reflectivity in the bright or color state versus the reflectivity in the dark state. What constitutes a sufficient contrast ratio depends on the desired application. Each of the three color IMOD types can be made sufficiently dark for practical visibility of the display when the reflective ratio of bright or “on” states (closed for the illustrated implementation) to dark or “off” states (open for the illustrated implementation) is greater than, e.g., 3:1. A contrast ratio greater than, e.g., 10:1 approaches print quality. As described below with reference to Table I, in one example of the illustrated implementation, contrast ratio for each IMOD type of an RGB substantially exceeds 10:1 comparing each IMOD types' bright state to its own dark state. In fact, each IMOD type exceeds a 10:1 ratio comparing all of the IMOD types' bright states to its own dark state.

In some implementations, the first and second absorber layers 810 and 830 include MoCr to produce a substantially uniform dark appearance. The illustrated implementation represents a low reflectivity configuration in the open state, where the resulting pixel display is dark. This implementation carries potential display product applications, such as mobile phones appearing dark when turned off. Alternatively, the first and second absorber layers 810 and 830 can include Ge to produce a substantially uniform white appearance. This implementation can represent a high reflectivity configuration, and can potentially be used in display product applications, such as electronic paper or eBooks appearing white when turned off.

FIG. 8B shows an example of a schematic cross section of the interferometric modulators of FIG. 8A in the closed state. In the closed state, each IMOD structure 800a, 800b or 800c can be configured to reflect light of a particular color depending on the different optical paths set by the different optical stacks 16. When a voltage is applied to one of the IMOD structures 800a, 800b or 800c, the movable reflective layer 850 of that device is electrostatically attracted to the optical stack 16. The movable reflective layer 850 may include Al, AlCu alloy, or a similar reflective material. In some implementations, the movable reflective layer 850 includes or is attached to a flexible membrane that is in tensile stress formed over an Al thin film. The movable reflective layer 850 can include a dielectric (e.g., SiON) mechanical layer integrated with similar conductor layers above and below for more balanced stresses. Moreover, the movable layer 850 may further include a very thin dielectric passivation layer (not shown) so that a second absorber layer 830 would not contact an electrical conductor when the electromechanical system device is in the closed state.

The movable reflective layer 850 and/or other conductive layers associated with it can function as a moving electrode that is electrostatically attracted to a transparent conductor incorporated in the optical stack 16. In some implementations, an ITO layer can be formed between the absorber layer 810 and the substrate 805. In some other implementations, one or both of the absorber layers 810 and 830 can serve as the stationary electrode. In some implementations, a transparent conductive material may be formed between the absorber layer 830 and the transparent solid layer 820, or alternatively, can be used as the transparent solid layer. A potential advantage for placing the stationary electrodes proximate the uniformly sized gaps is that the movable reflective layer 850 need not have different stiffnesses for each IMOD structure 800a, 800b and 800c to maintain a single actuation voltage to collapse IMODs for different colors or shades. Different-sized air gaps may sometimes call for compensation with different mechanical layer stiffnesses to maintain a constant voltage. Yet with a constant air gap 840, a single actuation voltage can be employed for the different IMODs without altering stiffness, which improves power consumption as well as eliminates complex fabrication issues for achieving varied stiffness.

FIG. 8C shows an example of a schematic cross section of another implementation showing three different interferometric modulators, all three shown in the open state having a constant air gap and three different dielectric materials. Each IMOD structure 800a, 800b and 800c includes a transparent solid layer 820 having three different materials, such as combinations of SiO₂, SiOₓN_{y}, Al₂O₃, TiO₂, ZrO₂, HfO₂, In₂O₃, SnO₂, ZnO, SiN, or mixtures thereof. By having three different materials, each IMOD structure 800a, 800b and 800c may have a different index of refraction (e.g., SiO₂ has an index of refraction of ˜1.46, SiON is ˜1.49, and Al₂O₃ is ˜1.78), which corresponds to different optical path lengths. Therefore, each IMOD structure may be configured to reflect light of a different color or shade corresponding to different dielectric materials. It is appreciated that by varying dielectric materials, the thickness of each dielectric material may be made close to one another (e.g., within ±200 Å) or even identical for the different IMOD types or colors, thus reducing topography and related problems.

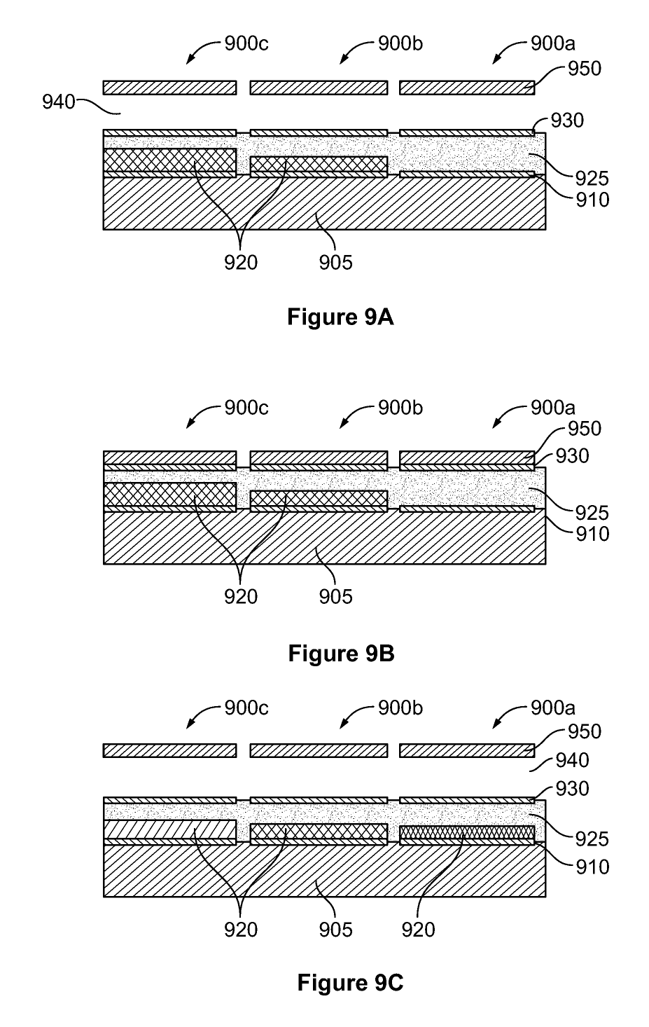

FIG. 9A shows an example of a schematic cross section of an alternative implementation showing three different interferometric modulators having a constant air gap and a planarization layer formed over dielectric layers of different thicknesses. The planarization layer 925 may be a transparent dielectric and formed over a transparent solid layer 920 (at least for some of the IMOD types), and may operate to substantially planarize the surface between the air gap 940 and the transparent solid layer 920. The planarization layer 925 can have a different thickness for each IMOD structure 900a, 900b and 900c and can complement the different thicknesses of the transparent solid layer 920 to define a uniform total thickness of the transparent solid layer 920 and the planarization layer 925. The planarization layer 925 may include a curable polymer or spin-on dielectric, such as a silicate or siloxane based spin-on glass material. In some implementations, the transparent solid layer 920 can have a different index of refraction from the planarization layer 925, including, e.g., TiO₂, Al₂O₃, or other substantially transparent dielectric materials. The different thicknesses of the two materials for the different IMOD types can provide different optical path lengths to define the reflected color or shade.

FIG. 9B shows an example of a schematic cross section of the interferometric modulators of FIG. 9A in the closed state. Each IMOD structure 900a, 900b or 900c is configured to reflect light of a different color or shade in the collapsed state. For highly accurate thickness control of the planarization layer 925, a coat-then-etch back process may be used, in which the planarization layer 925 is first coated and its thickness measured, and then an etch back process is performed until the thickness is reduced to the desired level.

FIG. 9C shows an example of a schematic cross section of another implementation showing three different interferometric modulators in the open state having a constant air gap and a planarization layer formed over three different dielectric materials. The materials have different indices of refraction and can therefore be made with similar thicknesses while achieving different optical path lengths. The planarization layer 925 compensates for the slight variations in thicknesses by planarizing the surface between the air gap 940 and the transparent solid layer 920.

In some implementations, the absorber layers can affect the color purity for a particular wavelength of color. One way of measuring the color purity is by a reflectivity curve. Theoretical reflectivity curves plot the amount of reflectance of visible light against wavelength and can indicate expected reflectance, color saturation, reflectivity peak, and reflectivity half-peak width for the modeled materials and dimensions.

In FIGS. 9A-C, each IMOD structure 900a, 900b or 900c includes an air gap having a height of about 1250 Å in the open state. In addition, each IMOD structure 900a, 900b or 900c includes a dielectric layer forming each respective transparent layer of varying thicknesses, with a first IMOD 900a structure having a dielectric thickness of about 1360 Å, a second IMOD structure 900b having a dielectric thickness of about 1720 Å, and a third IMOD structure 900c having a dielectric thickness of about 2000 Å. Each dielectric layer is made of SiO₂ which has an index of refraction of about 1.46. Furthermore, each IMOD structure 900a, 900b or 900c includes two absorbers situated on opposite sides of the dielectric layers. The two absorbers are made of MoCr having a thickness of 25 Å each. In the collapsed state, the air gap for each IMOD structure collapses to approach a 0 Å limit, but does not necessarily reach 0 Å due to certain limitations, e.g., surface roughness.

FIGS. 10A-C illustrate exemplary reflectivity curves for a red-green-blue color spectrum of the aforementioned IMOD structures 800a, 800b and 800c. The first, second, and third IMOD structures 800a, 800b and 800c correspond to a blue, green, and red color spectrum respectively. Table I reveals exemplary parameters for the red, green, and blue wavelengths in both the open and collapsed states, and their respective reflectivity percentages and photopic integrated reflectivity percentages.

Photopic integrated reflectivity is calculated by integrating the product of the reflectivity R(λ) multiplied by an eye spectral response factor—E. The eye spectral response factor E describes the variation of eye sensitivity with respect to different wavelengths. In some implementations, a green photon will appear brighter than a blue photon due to eye sensitivity when exposed to certain colors. Therefore, a photopic integration of reflectivity provides a more informative measure of how bright/dark an image will appear to, e.g., a viewer.

FIG. 10A shows an example of a reflectivity curve for a blue interferometric modulator in open and closed states in accordance with a constant gap implementation. Along the y-axis, the reflectivity value is shown along a scale of 0.0 to 0.8, which converts to a percentage value by multiplying the value by 100. Along the x-axis, the wavelength is measured in nanometers (nm) in the range of 350 nm to 800 nm. A reflectivity curve 1010 exhibits a peak at 450 nm having a reflectance of 73.5% in the closed state. In the open state, a reflectivity curve 1020 exhibits a reflectance of 0.8%. At the peak wavelength, contrast ratio may be calculated by taking the peak reflectivity value of curve 1010 divided by the reflectivity value of curve 1020. In this case, the contrast ratio at the peak wavelength is about [91:1].

FIG. 10B shows an example of a reflectivity curve for a green interferometric modulator in open and closed states, having the same gap in the open state as the blue interferometric modulator of FIG. 10A. A reflectivity curve 1030 exhibits a peak at 550 nm having a reflectance of 77.6% in the closed state. In the open state, a reflectivity curve 1040 exhibits a reflectance of 0.8%. In this instance, the contrast ratio when dividing the peak reflectivity value at curve 1030 by the reflectivity value at curve 1040 at the peak wavelength is about [97:1].

FIG. 10C shows an example of a reflectivity curve for a red interferometric modulator in open and closed states, having the same gap in the open state as the blue and green interferometric modulators of FIGS. 10A and 10B. A reflectivity curve 1050 exhibits a peak at 630 nm having a reflectance of 80% in the closed state. In the open state, a reflectivity curve 1060 exhibits a reflectance of 1.4%. In this case, the contrast ratio when dividing the peak reflectivity value at curve 1050 by the reflectivity value at curve 1060 at the peak wavelength is about [57:1].

FIGS. 10A-C demonstrate that the exemplary IMOD structures 800a, 800b and 800c produce well-defined colors in the closed state. FIGS. 10A-C also show that the exemplary IMOD structures produce a substantially similar dark appearance in the open state, with a minimal reflectivity at the wavelengths corresponding to the peaks of the individual colors. As noted above, the sufficiency of the dark appearance can be determined by the contrast ratio. For example, an IMOD device with a contrast ratio greater than 3:1 may have a sufficiently dark appearance. In other applications, a contrast ratio greater than 10:1 approaches print quality. For the example of FIGS. 10A-C, the contrast ratio for each IMOD exceeds both measures for the dark state of each device type (color) compared against the bright state of all three devices (colors). Therefore, all three IMOD structures produce a substantially similar dark appearance in the open state, despite having different optical path lengths in the open state. Further optimization of the reflectivity spectrum in the dark state is possible by selecting particular combinations of the materials in stack 16 such that the combination of the wavelength dependences of their complex refractive indices results in minimizing the reflectivity across a wider range of visible wavelengths around the corresponding peak wavelength.

TABLE I

| | | Dielec- | Reflec- | Contrast | Photopic |
|---|---|---|---|---|---|
| | Air | tric | tivity | Ratio at | Integrated |
| | Gap | Layer | Percentage | peak | Reflectivity |
| | (Å) | (Å) | (peak) | wavelength | Percentage |
| Blue (peak = | 0 | 1360 | 73.5% | 91:1 | 41.5% |
| 450 nm) | | | | | |
| Unactuated | 1250 | 1360 | 0.8% | | 7.2% |
| Green (peak = | 0 | 1720 | 77.6% | 97:1 | 70.7% |
| 550 nm) | | | | | |
| Unactuated | 1250 | 1720 | 0.8% | | 1.8% |
| Red (peak = | 0 | 2000 | 80.0% | 57:1 | 52.7% |
| 630 nm) | | | | | |
| Unactuated | 1250 | 2000 | 1.4% | | 2.00% |

The provision of the second absorber layer can change the reflectivity characteristics in one of the parameters of reflectance, color saturation, reflectivity peak, and reflectivity half-peak width relative to an IMOD without a second absorber layer. At least one of the different IMOD types includes first and second absorber layers on either side of a transparent layer in the optical stack. The resultant narrower reflectivity peak represents sharpened color saturation or contrast. One or more of the different IMOD types can be provided with the second absorber, as desired to sharpen color saturation for particular IMOD types, such as red IMODs. In one example, the optical path length through the transparent solid layer may equal the optical path length through the air gap. D1*refractive_index(dielectric)=D2*refractive_index(air). D1 describes the thickness of the transparent solid layer, or in some implementations, the distance between the two absorbers. D2 describes the thickness of the air gap. By adjusting thicknesses and the material compositions of the first and second absorber layers, whether or not the first and second absorber layers have the same thicknesses and material compositions, it is also possible to enhance the reflectivity, and thereby improve contrast ratio, of the reflected color for selected IMOD types.

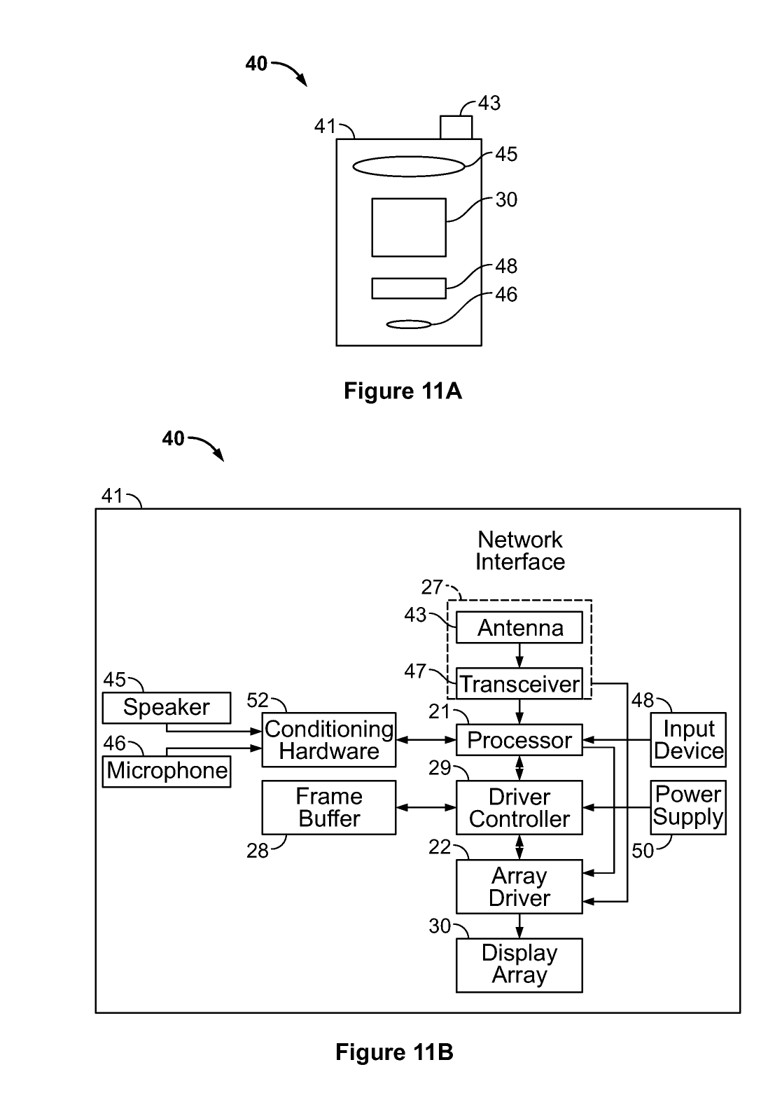

FIGS. 11A and 11B show examples of system block diagrams illustrating a display device 40 that includes a plurality of interferometric modulators. The display device 40 can be, for example, a cellular or mobile telephone. However, the same components of the display device 40 or slight variations thereof are also illustrative of various types of display devices such as televisions, e-readers and portable media players.

The display device 40 includes a housing 41, a display 30, an antenna 43, a speaker 45, an input device 48, and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber, and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an interferometric modulator display, as described herein.

The components of the display device 40 are schematically illustrated in FIG. 11B. The display device 40 includes a housing 41 and can include additional components at least partially enclosed therein. For example, the display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (e.g., filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. A power supply 50 can provide power to all components as required by the particular display device 40 design.

The network interface 27 includes the antenna 43 and the transceiver 47 so that the display device 40 can communicate with one or more devices over a network. The network interface 27 also may have some processing capabilities to relieve, e.g., data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g or n. In some other implementations, the antenna 43 transmits and receives RF signals according to the BLUETOOTH standard. In the case of a cellular telephone, the antenna 43 is designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G or 4G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that is readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation, and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of pixels.

In some implementations, the driver controller 29, the array driver 22, and the display array 30 are appropriate for any of the types of displays described herein. For example, the driver controller 29 can be a conventional display controller or a bi-stable display controller (e.g., an IMOD controller). Additionally, the array driver 22 can be a conventional driver or a bi-stable display driver (e.g., an IMOD display driver). Moreover, the display array 30 can be a conventional display array or a bi-stable display array (e.g., a display including an array of IMODs). In some implementations, the driver controller 29 can be integrated with the array driver 22. Such an implementation is common in highly integrated systems such as cellular phones, watches and other small-area displays.

In some implementations, the input device 48 can be configured to allow, e.g., a user to control the operation of the display device 40. The input device 48 can include a keypad, such as a QWERTY keyboard or a telephone keypad, a button, a switch, a rocker, a touch-sensitive screen, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices as are well known in the art. For example, the power supply 50 can be a rechargeable battery, such as a nickel-cadmium battery or a lithium-ion battery. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

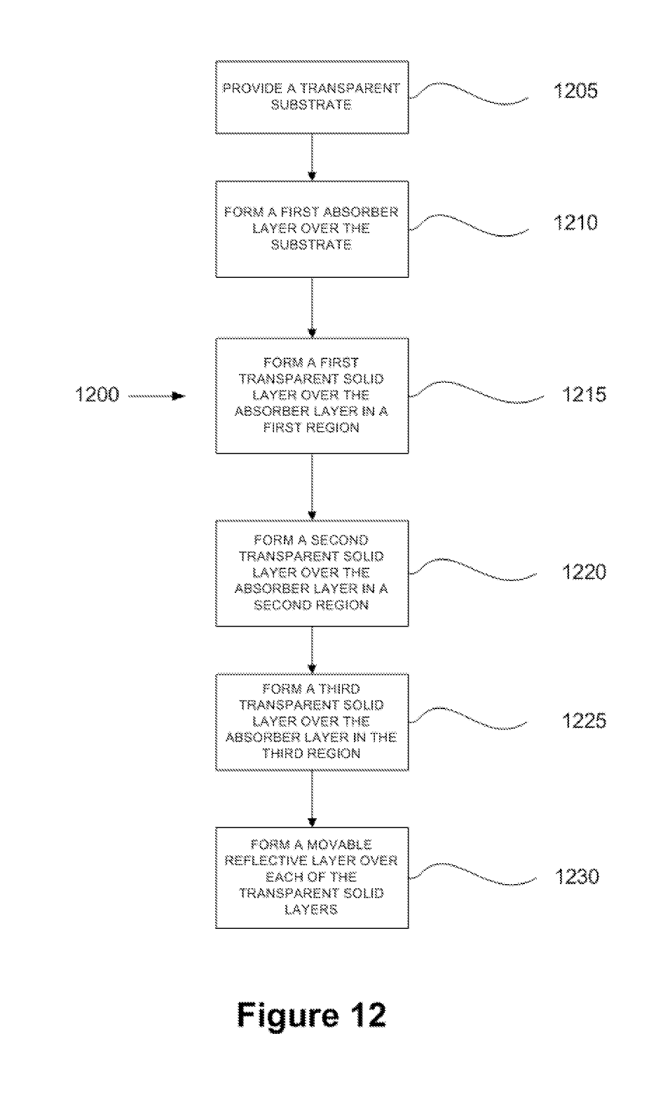

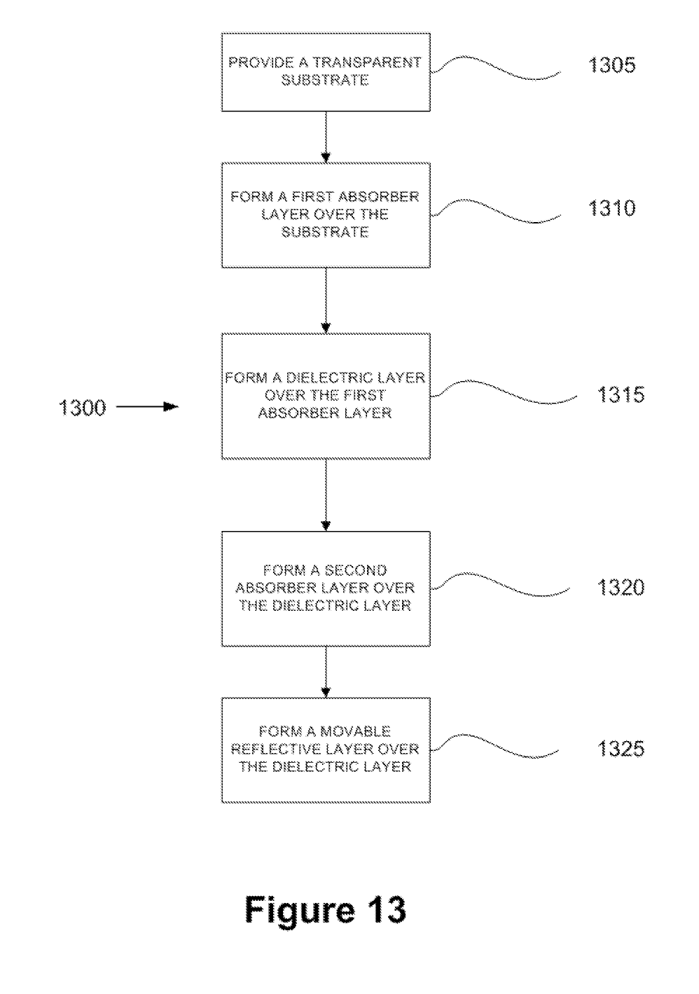

FIG. 12 shows an example of a flow diagram illustrating the manufacturing process for an interferometric modulator. Such steps may be present in a process for manufacturing IMODs of the general type illustrated in FIGS. 1-7E, along with other steps not shown in FIGS. 12 and 13. For example, it will be understood that additional processes of depositing underlying or intervening layers, such as black mask layers, bussing layers, and absorber layers may be present.

With reference to FIG. 12, the process 1200 illustrates a method of manufacturing a first IMOD, a second IMOD and a third IMOD in a first region, a second region and a third region, respectively. The process 1200 begins at block 1205 where a transparent substrate is provided. The process 1200 continues at block 1210 where a first absorber layer is formed over the substrate. The process 1200 then continues at block 1215 where a first transparent solid layer is formed over the absorber layer in a first region. The process 1200 then continues at block 1220 where a second transparent solid layer is formed over the absorber layer in the second region. The process 1200 then continues at block 1225 where a third transparent solid layer is formed over the absorber layer in the third region. The process 1200 then continues at block 1230 where a movable reflective layer is formed over each of the transparent solid layers, and has open and collapsed states. The movable reflective layer and each of the transparent solid layers define a gap between them in the open state, where the gap has the same height in the first, second and third regions. The first, second and third transparent solid layers each define different optical path lengths representing different colors for one of the open and collapsed states in the first, second, and third regions, respectively.

FIG. 13 shows another example of a flow diagram illustrating a manufacturing process for an interferometric modulator. With reference to FIG. 13, the process 1300 begins at block 1305 where a transparent substrate is provided. The process 1300 continues at block 1310 where a first absorber layer is formed over the substrate. The process 1300 then continues at block 1315 where a dielectric layer is formed over the first absorber layer. The process 1300 then continues at block 1320 where a second absorber layer is formed over the dielectric layer. The process 1300 then continues at block 1325 where a movable reflective layer, having open and collapsed states, is formed over the dielectric layer. The dielectric layer and the reflective layer define a gap therebetween in the open state.

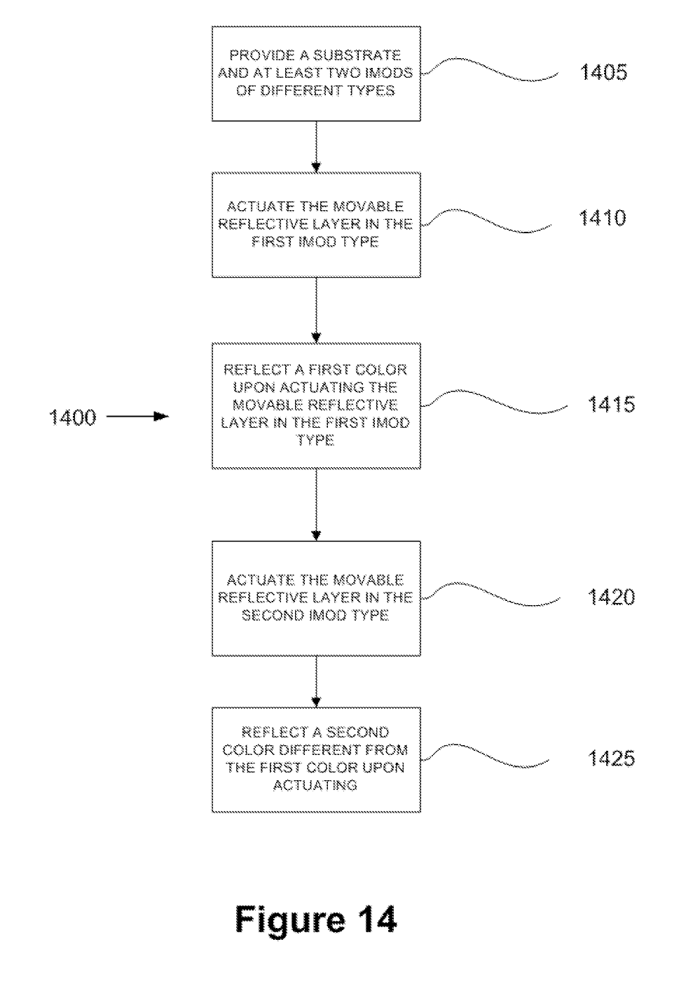

FIG. 14 shows an example of a flow diagram illustrating a method of operating an electromechanical interferometric modulator device. With reference to FIG. 14, the method 1400 begins at block 1405 by providing a substrate and at least two IMODs of different types. Each of the at least two IMODs of different types can include an optical stack formed on the substrate, a movable reflective layer, and a gap defined between the movable reflective layer and the optical stack. The optical stack can further include a dielectric layer and an absorber layer formed between the dielectric layer and the substrate. The method 1400 continues at block 1410 by actuating the movable reflective layer in a first IMOD type of the at least two IMODs of different types toward the optical stack to substantially close the gap in the first IMOD type. The method 1400 then continues at block 1415 by reflecting a first color upon actuating the movable reflective layer in the first IMOD type. The method 1400 further continues at block 1420 by actuating the movable reflective layer in a second IMOD type of the at least two IMODs of different types toward the optical stack to substantially close the gap in the second IMOD type. Then the method 1400 continues at block 1425 by reflecting a second color different from the first color upon actuating the movable reflective layer in the second IMOD type.

Various modifications to the implementations described in this disclosure may be readily apparent to those skilled in the art, and the generic principles defined herein may be applied to other implementations without departing from the spirit or scope of this disclosure. Thus, the disclosure is not intended to be limited to the implementations shown herein, but is to be accorded the widest scope consistent with the claims, the principles and the novel features disclosed herein. The word “exemplary” is used exclusively herein to mean “serving as an example, instance, or illustration.” Any implementation described herein as “exemplary” is not necessarily to be construed as preferred or advantageous over other implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of the IMOD as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

1. An electromechanical interferometric modulator (IMOD) system comprising:
a substrate;
a first IMOD comprising a first optical stack formed on the substrate, wherein the first optical stack comprises:
a first absorber layer;
a first movable reflective layer, wherein the first movable reflective layer has at least first open and first collapsed states; and
a first gap defined between the first movable reflective layer and the first optical stack in the first open state;
a second IMOD comprising a second optical stack formed on the substrate, wherein the second optical stack comprises:
a second absorber layer;
a second movable reflective layer, wherein the second movable reflective layer has at least second open and second collapsed states; and
a second gap defined between the second movable reflective layer and the second optical stack in the second open state;
wherein the second IMOD corresponds to a different reflected visible wavelength from the first IMOD in one of the states, the second optical stack defining a different optical path length from the first optical stack, and the second gap being the same size as the first gap in the first and second open states, respectively.

2. The electromechanical interferometric modulator system of claim 1, wherein the first optical stack comprises a first transparent solid layer between the first absorber layer and the first movable reflective layer, wherein the second optical stack comprises a second transparent solid layer between the second absorber layer and the second movable reflective layer, the second transparent solid layer having a different thickness than the first transparent solid layer.

3. The electromechanical interferometric modulator system of claim 2, wherein each of the transparent solid layers comprises a transparent conductor.

4. The electromechanical interferometric modulator system of claim 2, wherein each of the transparent solid layers is a dielectric.

5. The electromechanical interferometric modulator system of claim 2, wherein the first optical stack further comprises an additional first absorber layer between the first transparent solid layer and the first gap in the first open state, and the second optical stack further comprises an additional second absorber layer between the second transparent solid layer and the second gap in the second open state.

6. The electromechanical interferometric modulator system of claim 5, wherein the first, second, additional first, and additional second absorber layers each comprises a metallic or semiconducting material having a semi-reflective thickness.

7. The electromechanical interferometric modulator system of claim 5, wherein the first and second collapsed define different colors for the first and second IMOD, and the first and second open define a common color appearance for the first and second IMOD.

8. The electromechanical interferometric modulator system of claim 7, wherein the common color appearance in the open states is dark.

9. The electromechanical interferometric modulator system of claim 8, wherein each of the first and second IMODs defines a contrast ratio of at least 3:1, wherein the contrast ratio is a ratio of reflectivity in the respective collapsed state relative to reflectivity in the respective open state.

10. The electromechanical interferometric modulator system of claim 2, comprising an array of pixels, each pixel comprising the first IMOD, the second IMOD, and a third IMOD, wherein the three IMODs within each pixel define three different colors in the respective collapsed states, the third IMOD comprising a third optical stack formed on the substrate, wherein the third optical stack comprises:
a third absorber layer;
a third movable reflective layer, wherein the third movable reflective layer has at least third open and third collapsed states;
a third gap defined between the third movable reflective layer and the third optical stack in the third open state; and
a third transparent solid layer between the third absorber layer and the third movable reflective layer, the third transparent solid layer having a different thickness than the first transparent solid layer and the second transparent solid layer, and the third gap being the same size as the first and second gaps in the respective open states.

11. The electromechanical interferometric modulator system of claim 5, wherein
the first optical stack further comprises a first planarization layer between the first transparent solid layer and the first gap,
the second optical stack further comprises a second planarization layer between the second transparent solid layer and the second gap,
the second planarization layer having a different thickness than the first planarization layer, the different thicknesses of the first and the second planarization layers complementing the different thicknesses of the first and the second transparent solid layers to define a uniform total thickness of the first and the second optical stacks, and wherein
the first transparent solid has a refractive index different from the refractive index of the first planarization layer and
the second transparent solid has a refractive index different from the refractive index of the second planarization layer.

12. The electromechanical interferometric modulator system of claim 11, wherein the additional first absorber layer is between the first planarization layer and the first gap in the first open state, and the additional second absorber layer is between the second planarization layer and the second gap in the second open state.

13. The electromechanical interferometric modulator system of claim 10, wherein the array of pixels forms a color display.

14. The electromechanical interferometric modulator system of claim 1, further comprising:
a display;
a processor that is configured to communicate with said display, the processor being configured to process image data; and
a memory device that is configured to communicate with the processor.

15. The electromechanical interferometric modulator system of claim 14, further comprising a driver circuit configured to send at least one signal to the display, and a controller configured to send at least a portion of the image data to the driver circuit.

16. The electromechanical interferometric modulator system of claim 14, further comprising an image source module configured to send the image data to the processor.

17. An electromechanical interferometric modulator color display system comprising:
a substrate; and
a plurality of interferometric modulators (IMODs), each IMOD comprising:
an optical stack formed on the substrate, wherein the optical stack comprises a dielectric layer, a first absorber layer on one side of the dielectric layer and a second absorber layer on an opposite side of the dielectric layer,
a movable reflective layer, wherein the movable reflective layer has at least open and collapsed states, and
an air gap defined between the movable reflective layer and the optical stack in the open state.

18. The electromechanical interferometric modulator color display system of claim 17, wherein the plurality of IMODs comprise at least two different IMOD types, the collapsed state defining different colors for each of the at least two different IMOD types, and the open state defining a substantially low reflectivity relative to the collapsed state for each of the at least two different IMOD types.

19. The electromechanical interferometric modulator color display system of claim 17, wherein the plurality of IMODs comprise at least two different IMOD types, and wherein the open state defines a substantially dark appearance for each IMOD type.

20. The electromechanical interferometric modulator color display system of claim 19, wherein each of the IMOD types defines a contrast ratio of at least 3:1, wherein the contrast ratio is a ratio of reflectivity in the collapsed state relative to reflectivity in the open state.

21. The electromechanical interferometric modulator color display system of claim 17, wherein the plurality of IMODs comprise at least two different IMOD types representing different colors, and wherein the gap has the same height in the open state for each of the at least two different IMOD types.

22. The electromechanical interferometric modulator color display system of claim 17, wherein the plurality of IMODs comprise at least two different IMOD types representing different interferometrically enhanced colors, and wherein the optical stack defines different optical path lengths for each of the at least two different IMOD types.

23. An electromechanical systems device, comprising:
a substrate;
a stationary electrode over the substrate, the stationary electrode comprising:
a first absorber layer over the substrate,
a transparent solid layer over the first absorber layer, and
a second absorber layer over the dielectric layer; and
a movable electrode over the stationary electrode, the movable electrode having at least open and collapsed states, the stationary electrode and the movable electrode defining a gap therebetween in the open state.

24. The electromechanical systems device of claim 23, wherein the electromechanical systems device is configured to interferometrically reflect a substantially dark appearance in the open state.

25. An electromechanical interferometric modulator system with at least two different interferometric modulator (IMOD) types for reflecting corresponding different colors, comprising:
means for supporting the electromechanical interferometric modulator system;
means for defining optical path length within each of the at least two different IMOD types, the means for defining optical path length being different for each of the at least two different IMOD types and being positioned over the means for supporting;
first means for absorbing light, the first means for absorbing positioned between the means for defining optical path length and the means for supporting for each of the at least two different IMOD types;
means for reflecting light, the means for reflecting positioned over the means for defining optical path length for each of the at least two different IMOD types; and
means for moving the means for reflecting through a commonly sized gap for each of the at least two different IMOD types, the means for moving defining at least open and collapsed states.

26. The electromechanical interferometric modulator system of claim 25, wherein the means for defining optical path length each comprise a transparent solid dielectric material.

27. The electromechanical interferometric modulator system of claim 26, wherein the transparent solid layer has a different thickness for each of the at least two different IMOD types.

28. The electromechanical interferometric modulator system of claim 26, wherein the transparent solid layer comprises a different material for each of the at least two different IMOD types.

29. The electromechanical interferometric modulator system of claim 25, further comprising second means of absorbing light, the second means for absorbing positioned between the means for defining optical path length and the gap for each of the at least two different IMOD types.

30. The electromechanical interferometric modulator system of claim 29, wherein the means for defining optical path length further comprises means for planarizing the surface between the gap and each of the means for defining optical path length.

31. The electromechanical interferometric modulator system of claim 25, wherein the means for moving comprises a first electrode and a second electrode, the first electrode positioned on one side of the gap and the second electrode positioned on the other side of the gap for each of the at least two different IMOD types.

32. The electromechanical interferometric modulator system of claim 25, wherein the means for defining optical path length produces different colors for each of the at least two different IMOD types in the collapsed state.

33. A method of manufacturing at least a first electromechanical interferometric modulator (IMOD), a second IMOD, and a third IMOD in first, second, and third regions, respectively, the method comprising:
providing a transparent substrate;
forming a first absorber layer over the substrate;
forming a first transparent solid layer over the absorber layer in the first region;
forming a second transparent solid layer over the absorber layer in the second region;
forming a third transparent solid layer over the absorber layer in the third region; and
forming a movable reflective layer over each of the transparent solid layers, wherein the movable reflective layer has at least open and collapsed states, the movable reflective layer and each of the transparent solid layers defining a gap therebetween in the open state, and wherein the gap has the same height in the open state in the first, second, and third regions;
wherein the first, second, and third transparent solid layers each define different optical path lengths representing different colors for one of the open and collapsed states in the first, second, and third regions, respectively.

34. The method of claim 33, wherein forming the third transparent solid layer comprises forming a planarization layer, the planarization layer defining a substantially planar surface at a common height above the substrate in each of the first, second, and third regions between the gap and the corresponding transparent solid layer.

35. The method of claim 33, further comprising forming a second absorber layer between the gap and each of the first, second, and third transparent solid layers.

36. A method of manufacturing an electromechanical interferometric modulator device, the method comprising:
providing a transparent substrate;
forming a first absorber layer over the substrate;
forming a dielectric layer over the first absorber layer;
forming a second absorber layer over the dielectric layer; and
forming a movable reflective layer over the dielectric layer, wherein the movable reflective layer has at least open and collapsed states, the dielectric layer and the reflective layer defining a gap therebetween in the open state.

37. The method of claim 36, wherein forming the movable reflective layer comprises:
depositing a sacrificial layer over the dielectric layer;
depositing a movable reflective layer over the sacrificial layer; and
removing the sacrificial layer to form the gap between the movable reflective layer and the dielectric layer.

38. A method of operating an electromechanical interferometric modulator device, the method comprising:
providing a substrate and at least two IMODs of different types, and wherein each of the at least two IMODs of different types further comprises: an optical stack formed on the substrate, a movable reflective layer, and a gap defined between the movable reflective layer and the optical stack, wherein the optical stack further comprises a dielectric layer and an absorber layer formed between the dielectric layer and the substrate;
actuating the movable reflective layer in a first IMOD type of the at least two IMODs of different types toward the optical stack to substantially close the gap in the first IMOD type;
reflecting a first color upon actuating the movable reflective layer in the first IMOD type;
actuating the movable reflective layer in a second IMOD type of the at least two IMODs of different types toward the optical stack to substantially close the gap in the second IMOD type; and
reflecting a second color different from the first color upon actuating the movable reflective layer in the second IMOD type.

39. The method of claim 38, further comprising:
relaxing the movable reflective layer in the first IMOD type away from the optical stack to substantially open the gap in the first IMOD type;
producing an open state visible appearance upon relaxing the movable reflective layer in the first IMOD type;
relaxing the movable reflective layer in the second IMOD type away from the optical stack to substantially open the gap in the second IMOD type; and
producing substantially the same open state visible appearance upon relaxing the movable reflective layer in the second IMOD type.

40. The method of claim 38, wherein the movable reflective layer has at least open and closed states, the gap for each of the at least two IMODs of different types having the same height in the open state.
